(19) United States
(12) Patent Application Publication
(10) Pub. No.: US 2020/0144435 A1
(43) Pub. Date: May 7, 2020

(54) LIGHT CONTROL FILM

(71) Applicant: 3M INNOVATIVE PROPERTIES COMPANY, St. Paul, MN (US)

(72) Inventors: Gary E. Gaides, Woodbury, MN (US); Mark B. O'Neill, Stillwater, MN (US); Gary T. Boyd, Woodbury, MN (US)

(21) Appl. No.: 16/620,682

(22) PCT Filed: Jun. 6, 2018
(86) PCT No.: PCT/IB2018/054049

§ 371 Date: Dec. 9, 2019

Related U.S. Application Data
(60) Provisional application No. 62/518,820, filed on Jun. 13, 2017.
(60) Provisional application No. 62/520,836, filed on Jun. 16, 2017.

(51) Int. Cl. H01L 31/054; G02B 5/22; G02B 5/26; H02S 40/22

(52) U.S. Cl. CPC H01L 31/0547; G02B 5/223; H02S 40/22; H01L 31/0549; G02B 5/265

(57) ABSTRACT

Generally, the present disclosure relates to light control films. The present disclosure also relates to assemblies incorporating light control films. In some embodiments, the light control films of the present disclosure regulate transmission of one or more of visible light, ultraviolet light, and infrared light that reaches a substrate after exiting the light control film. The light control film comprises waveguiding channels (130) which collect light incident under larger incidence angles towards the surface opposite the incidence surface. The channels are surrounded by a material (140) having a lower refractive index than the one the channel material and can comprise an absorbing pigment.

The present disclosure generally relates to light control films and articles comprising them.

### BACKGROUND

Light control films (LCF) are optical films configured to regulate the transmission of light. Typical LCFs include a light transmissive film having a plurality of parallel grooves, which are formed of a light-absorbing material.

LCFs known in the art control visible light and are used in conjunction with the control of light available to displays. For example, LCFs can be placed proximate a display surface, image surface, or other surface to be viewed. At normal incidence, (i.e. 0 degree viewing angle) where a viewer is looking at an image through the LCF in a direction that is perpendicular to the film surface, the image is viewable. As the viewing angle increases, the amount of light transmitted through the LCF decreases until an external viewing cutoff angle is reached where substantially all (greater than about 95%) the light is blocked by the light-absorbing material and the image is no longer viewable. The LCF provides privacy to a viewer by blocking observation by others that are outside a typical range of viewing angles.

LCFs can be prepared by molding and ultraviolet curing a polymerizable resin on a polycarbonate substrate. Such LCFs are commercially available from 3M Company, St. Paul, Minn., under the trade designation “3M′ Filters for Notebook Computers and LCD Monitors.”

### SUMMARY

Generally, the present disclosure relates to light control films. The present disclosure also relates to assemblies incorporating light control films. In some embodiments, the LCFs regulate transmission of one or more of visible light, ultraviolet light, and infrared light, independently from each other, that reaches a substrate after exiting the light control film.

In one embodiment, this disclosure is directed to a light control film comprising a structured layer comprising a plurality of regions 1 alternating with a plurality of regions 2,
wherein the structured layer has a light input surface and a light output surface opposite the light input surface,
wherein the plane of the light input surface defines a plane for the film,
wherein at least one region 1 has a width at its base W_{1b}, a height H₁, and an index of refraction N₁,
wherein at least one region 2 has a width at its base W_{2b}, a height H₂, and an index of refraction N₂,
wherein the lesser of H₁ and H₂ is the effective height, H,
wherein a first interface between the at least one region 1 and the at least one region 2 forms a first interface angle, θ₁, measured clockwise from a direction normal to the plane of the film,
wherein a second interface between the at least one region 1 and the at least one region 2 forms a second interface angle, θ₂, measured counterclockwise from a direction normal to the plane of the film,
wherein 1.0≤H/W_{1b}≤2.1,
wherein the pitch, P, is the sum of W_{1b} and W_{2b},
wherein the ratio W₁ₐ/P is greater than 0.8.

See FIG. 1 for a schematic representation of the embodiment described above.

In certain preferred embodiments, regions 1 are substantially transmissive to visible light, ultraviolet light, and infrared light. However, the inventors contemplate that, in certain embodiments, the transmission properties of regions 1 with respect to visible light, ultraviolet light, and infrared light can be selectively modified for each of those three spectral regions independently of each other.

In certain preferred embodiments, regions 2 are not substantially transmissive to visible light, but may be transmissive to infrared and/or ultraviolet radiation. The inventors contemplate that, in certain embodiments, the transmission properties of regions 2 with respect to visible light, ultraviolet light, and infrared light can be selectively modified for each of those three spectral regions independently of each other. For instance, in some embodiments, regions 2 may be selectively absorptive to visible light, but may be substantially transmissive to either infrared or ultraviolet radiation, or to both.

All scientific and technical terms used herein have meanings commonly used in the art unless otherwise specified. The definitions provided herein are to facilitate understanding of certain terms used frequently in this application and are not meant to exclude a reasonable interpretation of those terms in the context of the present disclosure.

Unless otherwise indicated, all numbers in the description and the claims expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein. At the very least, and not as an attempt to limit the application of the doctrine of equivalents to the scope of the claims, each numerical parameter should at least be construed in light of the number of reported significant digits and by applying ordinary rounding techniques. Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviations found in their respective testing measurements.

The recitation of numerical ranges by endpoints includes all numbers subsumed within that range (e.g. a range from 1 to 5 includes, for instance, 1, 1.5, 2, 2.75, 3, 3.80, 4, and 5) and any range within that range.

Unless explicitly stated otherwise, any angular measure is expressed in degree units of measure.

As used in this specification and the appended claims, the singular forms “a”, “an”, and “the” encompass embodiments having plural referents, unless the content clearly dictates otherwise. As used in this specification and the appended claims, the term “or” is generally employed in its sense including “and/or” unless the content clearly dictates otherwise.

The term “adjacent” refers to the relative position of two elements, such as, for example, two layers, that are close to each other and may or may not be necessarily in contact with each other or that may have one or more layers separating the two elements as understood by the context in which “adjacent” appears.

The term “immediately adjacent” refers to the relative position of two elements, such as, for example, two layers, that are next to each other and in contact with each other and have no intermediate layers separating the two elements. The term “immediately adjacent,” however, encompasses situations where one or both elements (e.g., layers) have been treated with a primer, or whose surface has been modified to affect the properties thereof, such as etching, embossing, etc., or by surface treatments, such as corona or plasma treatment, etc. that may improve adhesion.

The term “optically clear” as used herein refers to an item (e.g., a film) that has a luminous transmittance of higher than 20% and that exhibits a haze value lower than 40%. Both the luminous transmission and the total haze can be determined using, for example, a BYK Gardner Haze-gard Plus (Catalog No. 4725) according to the method of ASTM-D 1003-13, Procedure A (Hazemeter).

The term “film” as used herein refers, depending on the context, to either a single layer article or to a multilayer construction, where the different layers may have been laminated, extruded, coated, or any combination thereof.

The term “ultraviolet spectrum,” “ultraviolet light,” or “ultraviolet radiation” as used herein refers to radiation in the in the range from 10 nm to 400 nm.

The term “visible light” or “visible spectrum” as used herein refers to refers to radiation in the visible spectrum, which in this disclosure is taken to be from 400 nm to 750 nm.

The term “near infrared spectrum,” “infrared spectrum,” “infrared light,” or “infrared radiation” as used herein refers to radiation in the in the range from 750 nm to 2500 nm.

The term “transmittance” as used herein refers to the percentage of energy in a given region of the electromagnetic spectrum (e.g., visible, infrared, or any other range) that is transmitted across a surface. Transmittance is measured in accordance with the method described in ASTM 1348-15.

The term “average reflectance” as used herein refers to the arithmetic average of the reflectance values within that range as is measured following the procedure in ASTM 1331-15. Spectral reflectance values within the range may vary with respect to the average. A reflectance value that varies by 5% from the average is considered in absolute percent such that if the average is 10% spectral reflectance values of 5% -15% are within 5% of the average.

The term “0° incidence angle transmittance” as used herein refers to the transmittance across a surface in a given region of the electromagnetic spectrum measured at zero degree angle with respect to a line perpendicular to the surface. For details on how to measure transmittance see details in the Examples section.

The term “30° incidence angle transmittance” as used herein in the context of a film having regions 2 refers to the transmittance across a surface in a given region of the electromagnetic spectrum measured at 30 degrees with respect to a line perpendicular to the surface in a plane perpendicular to the longitudinal direction of the region 2 layer. For instance, with respect to FIG. 3, the 30° angle is measured in the xy plane in a clockwise direction from the y axis.

The term “substantially transmissive” in the context of a given radiation range as used herein refers to a property of a material that allows at least 70% transmission of radiation in the given radiation range. While this disclosure refers to transmissive regions in some embodiments, light transmission through the transmissive regions includes diffusive scattering.

The term “substantially absorptive” in the context of a given radiation range as used herein refers to a property of a material that allows at most 30% transmission of radiation in the given radiation range.

As used herein, a value A is “substantially similar” to a value B if the value A is within plus/minus 5% of the value A.

The term “internal viewing angle” (ϕ_{I}) as used herein is defined by the geometry of the alternating regions 1 and 2, as shown in FIG. 1A and can be calculated as follows:

ϕ_{I}=180°−a tan[H/(W_{1b}+H·tan(θ₁)]−a tan[H/(W_{1b}+H·tan(θ₂)]

The details of one or more embodiments of the disclosure are set forth in the accompanying drawings and the description below. Other features, objects, and advantages of the present disclosure will be apparent from the description and drawings, and from the claims.

### BRIEF DESCRIPTION OF DRAWINGS

FIG. 1A is a cross-sectional view of an embodiment of a light control film.

FIG. 1B is a cross-sectional view of an embodiment of a light control film.

FIG. 1C is a cross-sectional view of an embodiment of a light control film.

FIG. 2 is a perspective view of an embodiment of a microstructured film article.

FIG. 3 is a perspective view of an embodiment of a light control film.

FIG. 4 is a perspective view of an embodiment of a light control film further comprising an adhesive layer and a release liner.

FIG. 5 is a plot of transmittance as a function of wavelength of certain working examples and comparative examples.

### SYMBOL NOMENCLATURE

θ₁ interface angle defined by interface 150 and the normal (160) to light output surface 110

θ₂ interface angle defined by interface 170 and the normal (160) to light output surface 110

θₛₗₐₙₜ slant angle

θ_{T} wall angle (also referenced as included angle)

θ₃₀ 30 degree angle at which the 30° incidence angle transmittance is measured

ϕ_{I} internal viewing angle

ϕ_{P} external viewing cutoff angle

ϕ arbitrary viewing angle or measurement angle

H effective height, the lesser of H₁ and H₂

H₁ height of region 1

H₂ height of region 2

N₁ refractive index of region 1

N₂ refractive index of region 2

P pitch (W₁ₐ+W₂ₐ, W_{1b}W_{2b})

W₁ₐ top width of region 1

W_{1b} base width of region 1

W₂ₐ top width of region 2

W_{2b} base width of region 2

100 light control film

110 light output surface

120 light input surface

130 region 1 (in some embodiments, this is a substantially transmissive region)

140 region 2 (in some embodiments, this is a spectrally selective absorptive region)

150 first interface between region 1 (130) and region 2 (140)

160 normal to light output surface 110

170 second interface between region 1 (130) and region 2 (140)

200 microstructured film article

201a groove

201b groove

201c groove

201d groove

210 microstructured surface

211 opposing surface

220 grooves

230 continuous land region

260 base substrate layer

300 light control film

350 region 2 material

400 light control film

410 adhesive layer

470 release liner

Like symbols in the figures refer to like elements.

### DETAILED DESCRIPTION

As mentioned previously, in one aspect of the present disclosure, a light control film includes a plurality of alternating regions 1 and regions 2 adjacent to each other and located between a light input surface and a light output surface. In certain embodiments, the LCFs of the present disclosure are designed so that the light entering the LCF undergoes total internal reflection (TIR) within the LCF, increasing the amount of light transmitted through the film. While typical LCFs are often made to ensure that the absorptive regions absorb as much of the incident light as possible, the present LCFs allow reflection from regions 2 and at least a portion of such reflected radiation is directed towards the light output surface of the film.

In preferred embodiments, the index of refraction of regions 1 is greater than the index of refraction of regions 2, such that the difference in refractive indices is not less than 0.005. In one aspect, the difference in the refractive indices is not less than 0.1; in another aspect, the difference is from 0.007 to 0.06. In other embodiments, the difference in the refractive indices is at least 0.05, or at least 0.06, or at least 0.07, or at least 0.08, or at least 0.09, or at least 0.1, or at least 0.11, or at least 0.12, or at least 0.13, or at least 0.14, or at least 0.15. As a result, light incident on an interface between a region 1 adjacent to a region 2 may undergo total internal reflection if the incident angle is greater than a critical angle. Thus, in some cases, light incident on the light control film is transmitted by the light control film, at least in part, by total internal reflection.

In one embodiment, this disclosure is directed to a light control film comprising a structured layer comprising a plurality of regions 1 alternating with a plurality of regions 2,
wherein the structured layer has a light input surface and a light output surface opposite the light input surface,
wherein the plane of the light input surface defines a plane for the film,
wherein at least one region 1 has a width at its base W_{1b}, a height H₁, and an index of refraction N₁,
wherein at least one region 2 has a width at its base W_{2b}, a height H₂, and an index of refraction N₂,
wherein the lesser of H₁ and H₂ is the effective height, H,
wherein a first interface between the at least one region 1 and the at least one region 2 forms a first interface angle, θ₁, measured clockwise from a direction normal to the plane of the film,
wherein a second interface between the at least one region 1 and the at least one region 2 forms a second interface angle, θ₂, measured counterclockwise from a direction normal to the plane of the film,
wherein 1.0≤H/W_{1b}≤2.1,
wherein the pitch, P, is the sum of W_{1b} and W_{2b},
wherein the ratio W₁ₐ/P is greater than 0.8.

In one embodiment, this disclosure is directed to a light control film comprising a structured layer comprising a plurality of regions 1 alternating with a plurality of regions 2,
wherein the structured layer has a light input surface and a light output surface opposite the light input surface,
wherein the plane of the light input surface defines a plane for the film,
wherein at least one region 1 has a width at its base W_{1b}, a height H₁, and an index of refraction N₁,
wherein at least one region 2 has a width at its base W_{2b}, a height H₂, and an index of refraction N₂,
wherein the lesser of H₁ and H₂ is the effective height, H,
wherein a first interface between the at least one region 1 and the at least one region 2 forms a first interface angle, θ₁, measured clockwise from a direction normal to the plane of the film,
wherein a second interface between the at least one region 1 and the at least one region 2 forms a second interface angle, θ₂, measured counterclockwise from a direction normal to the plane of the film,
wherein the 30° incidence angle transmittance of the film is at least 30% in at least one of the following wavelength ranges:
   from 300 nm to 400 nm,
   from 400 nm to 750 nm
   from 750 nm to 1500 nm.

In one embodiment, this disclosure is directed to a light control film comprising a structured layer comprising a plurality of regions 1 alternating with a plurality of regions 2,
wherein the structured layer has a light input surface and a light output surface opposite the light input surface,
wherein the plane of the light input surface defines a plane for the film,
wherein at least one region 1 has a width at its base W_{1b}, a height H₁, and an index of refraction N₁,
wherein at least one region 2 has a width at its base W_{2b}, a height H₂, and an index of refraction N₂,
wherein the lesser of H₁ and H₂ is the effective height, H,
wherein a first interface between the at least one region 1 and the at least one region 2 forms a first interface angle, θ₁, measured clockwise from a direction normal to the plane of the film,
wherein a second interface between the at least one region 1 and the at least one region 2 forms a second interface angle, θ₂, measured counterclockwise from a direction normal to the plane of the film,
wherein 1.0≤H/W_{1b}≤2.1,
wherein the pitch, P, is the sum of W_{1b} and W_{2b},
wherein the ratio W₁ₐ/P is greater than 0.8.
wherein a film made of the same material, and having the same transmittance as the at least one region 1, has a 0° incidence angle transmittance of at least 70% in at least two of the following wavelength ranges:
   from 300 nm to 400 nm,
   from 400 nm to 750 nm,
   from 750 nm to 1500 nm,
wherein a film made of the same material, and having the same transmittance as the at least one region 2, has a 0° incidence angle transmittance of at least 30% in one or two of the following wavelength ranges:
   from 300 nm to 400 nm,
   from 400 nm to 750 nm,
   from 750 nm to 1500 nm.

In other embodiments, this disclosure is directed to a light control film comprising a structured layer comprising a plurality of regions 1 alternating with a plurality of regions 2,
wherein the structured layer has a light input surface and a light output surface opposite the light input surface,
wherein the plane of the light input surface defines a plane for the film,
wherein at least one region 1 has a width at its base W_{1b}, a height H₁, and an index of refraction N₁,
wherein at least one region 2 has a width at its base W_{2b}, a height H₂, and an index of refraction N₂,
wherein the lesser of H₁ and H₂ is the effective height, H,
wherein a first interface between the at least one region 1 and the at least one region 2 forms a first interface angle, θ₁, measured clockwise from a direction normal to the plane of the film,
wherein a second interface between the at least one region 1 and the at least one region 2 forms a second interface angle, θ₂, measured counterclockwise from a direction normal to the plane of the film,
wherein 1.0≤H/W_{1b}≤2.1,
wherein the pitch, P, is the sum of W_{1b} and W_{2b},
wherein the ratio W₁ₐ/P is greater than 0.8.
wherein the total 0° incidence angle transmittance of the film is at least 75% in at least one of the following wavelength ranges:
   from 300 nm to 400 nm,
   from 400 nm to 750 nm
   from 750 nm to 1500 nm.

In one embodiment, this disclosure is directed to a light control film comprising a structured layer comprising a plurality of regions 1 alternating with a plurality of regions 2,
wherein the structured layer has a light input surface and a light output surface opposite the light input surface,
wherein the plane of the light input surface defines a plane for the film,
wherein at least one region 1 has a width at its base W_{1b}, a height H₁, and an index of refraction N₁,
wherein at least one region 2 has a width at its base W_{2 b}, a height H₂, and an index of refraction N₂,
wherein the lesser of H₁ and H₂ is the effective height, H,
wherein a first interface between the at least one region 1 and the at least one region 2 forms a first interface angle, θ₁, measured clockwise from a direction normal to the plane of the film,
wherein a second interface between the at least one region 1 and the at least one region 2 forms a second interface angle, θ₂, measured counterclockwise from a direction normal to the plane of the film,
wherein 1.0≤H/W_{1b}≤2.1,
wherein the pitch, P, is the sum of W_{1b} and W_{2b},
wherein the ratio W₁ₐ/P is greater than 0.8.
wherein θₛₗₐₙₜ is defined as the absolute value of [(θ₂ minus θ₁)/2],
wherein 0≤θₛₗₐₙₜ≤50,
wherein a film made of the same material, and having the same transmittance as the at least one region 1, has a 0° incidence angle transmittance of at least 70% in at least two of the following wavelength ranges:
   from 300 nm to 400 nm,
   from 400 nm to 750 nm,
   from 750 nm to 1500 nm,
wherein a film made of the same material, and having the same transmittance as the at least one region 2, has a 0° incidence angle transmittance of at least 30% in one or two of the following wavelength ranges:
   from 300 nm to 400 nm,
   from 400 nm to 750 nm,
   from 750 nm to 1500 nm.

In some embodiments, the film has an internal viewing angle, ϕ_{I}, wherein 50°≤ϕ_{I}≤88°.

Solar Assemblies

In certain preferred embodiments, the LCFs of the present disclosure may be applied to a solar photovoltaic cell (“PV cell”), or to an entire solar module. A surprising benefit of placing the LCF over a PV cell or module is that the LCF can hide or obscure the cell or module to observers viewing the cell or module from an angle greater than ½ of the external viewing cutoff angle, without significantly reducing incident solar radiation on the photovoltaic surface.

In general, PV cells are relatively small in size and typically combined into a physically integrated solar modules. PV modules are generally formed from two or more “strings” of PV cells, with each string consisting of two or more PV cells arranged in a row and typically electrically connected in series using tinned flat copper wires (also known as electrical connectors, tabbing ribbons, or bus wires). These electrical connectors are typically adhered to the PV cells by a soldering process.

A functional PV cell typically comprises the actual photovoltaic cell surrounded by an encapsulant, such as, for example, an EVA based or a polyolefin based encapsulant. In typical constructions, the PV cell includes encapsulant on both sides of the photovoltaic surface. A glass panel (or other suitable clear polymeric material) is bonded to each of the front and back sides of the encapsulant. The front panels are transparent to solar radiation and are typically referred to as the front-side layer or front-side cover. Back panels may be transparent, but are not required to be, and are usually referred to as the backside layer or backsheet. The front-side cover and the backsheet may be made of the same or a different material. Typically, the front-side cover is made of glass, but other transparent materials may also be used. The encapsulant is usually a transparent polymer material that encapsulates the PV cells and also is bonded to the front-side layer and the backsheet so as to physically seal off the photovoltaic surfaces. This laminated construction provides mechanical support for the PV cells and also protects them against damage due to environmental factors such as wind, snow, and ice. Typical PV modules are fit into a frame, usually made of metal, and has a sealant covering the edges of the module. The frame not only protects the edges of the module, but also provides additional mechanical strength to the entire assembly. However, not all modules comprise a frame.

In some embodiments, the LCFs of the present disclosure are placed over a single photovoltaic cell or over an entire solar module. The LCFs can be placed at different locations within the solar assembly. For instance, LCFs can be placed adjacent to the photovoltaic surface, embedded within the encapsulant, or adjacent the front-side layer, either next to the encapsulant or on the exterior surface of the front-side layer. In certain preferred embodiments, the LCF is placed adjacent to the front-side layer, between its interior surface and the encapsulant. An optically clear adhesive layer may be used to bond the LCFs to the desired substrate within the photovoltaic cell or solar module. In some embodiments, the LCFs of the present disclosure are placed external to the module on the front-side layer.

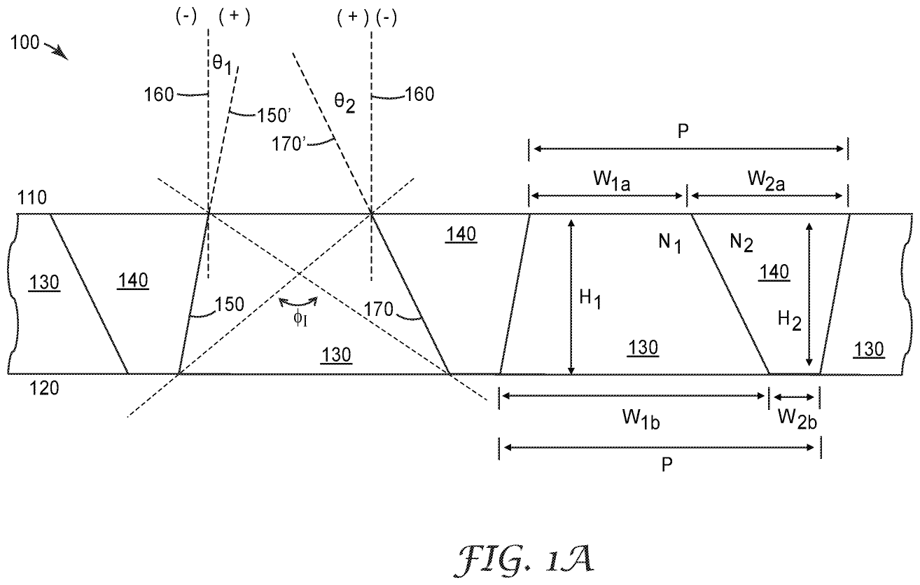

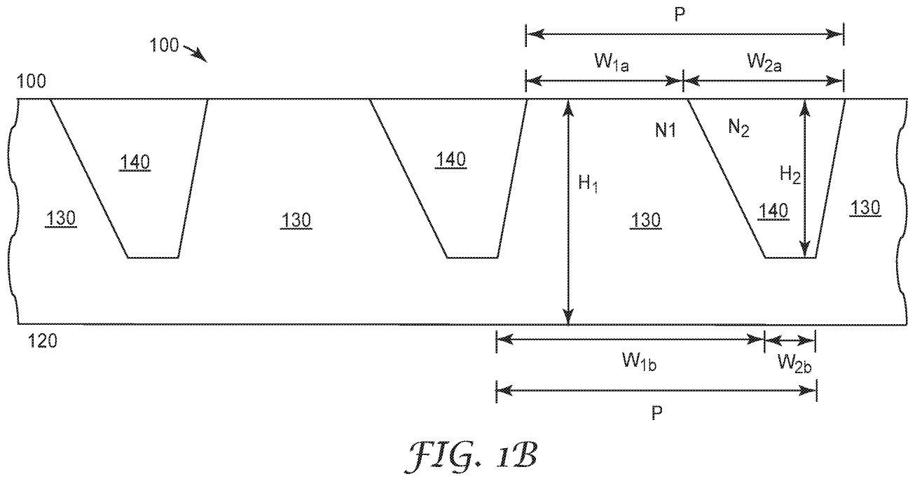

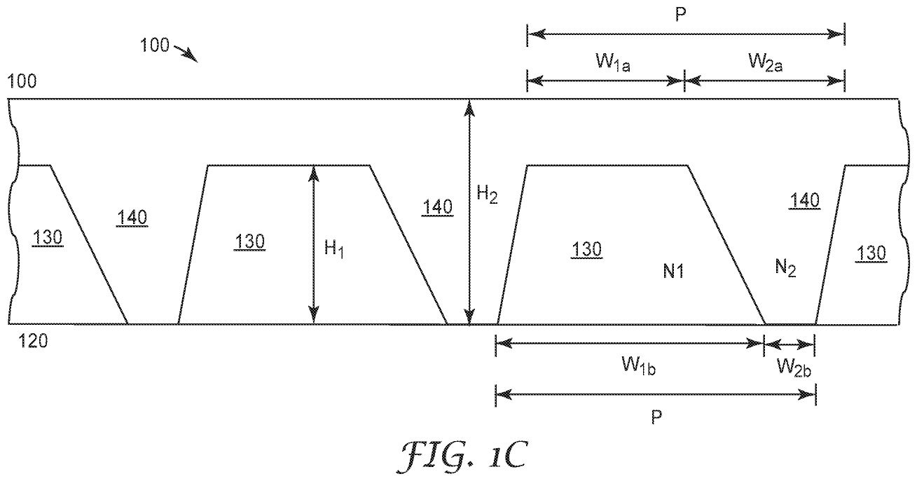

FIG. 1 shows a cross-sectional view of a light control film (LCF) 100 that includes a light input surface 120 and a light output surface 110 opposite the light input surface 120. The light input surface and light output surface are labeled for reference purposes only, but the LCFs of the present disclosure may be flipped upside down. That is, in some embodiments, the light output surface in the LCFs described herein may act as a light input surface and the light input surface may act as a light output surface, depending on the orientation of the film and the location of the light source.

The LCF (100) includes alternating regions 1 (130) and regions 2 (140). As mentioned previously, in certain preferred embodiments, regions 1 are substantially transmissive to visible light, ultraviolet light, and infrared light. In other embodiments, the transmission properties of the regions 1 can be adjusted so that they may be transmissive or absorptive in the visible, ultraviolet, and/or infrared spectra, with transmission or absorption in each spectral range being adjusted independently of the other ranges. In some embodiments, regions 2 (140) are spectrally selective absorptive regions and absorption is limited to particular wavelength ranges of the solar spectrum. In certain preferred embodiments, regions 2 are not substantially transmissive to visible light, but are transmissive to infrared and/or ultraviolet radiation. In other preferred embodiments, regions 1 are substantially transmissive to visible light, ultraviolet light, and infrared light, regions 2 are substantially transmissive to ultraviolet light and infrared light but are not substantially transmissive to visible light. First and second interfaces (150) and (170), respectively, are shown between regions 1 (130) and regions 2 (140).

The regions 1 (130) have a base width “W_{1b}”, a top width “W₁ₐ”, a thickness “H₁”, and a characteristic refractive index “N₁”. The regions 2 (140) in FIG. 1 have an inverted trapezoidal shape with a wide top width “W₂ₐ” proximate the light output surface of the LCF and a narrower base width “W_{2b}” proximate the light input surface. Regions 2 have a thickness “H₂”, and a characteristic refractive index “N₂”. Each “like” region (e.g. region 1) is disposed apart from adjacent “like” regions (e.g. an adjacent region 1) by a pitch “P,” which is the sum of W_{1b} plus W_{2b}, and which is also the same as the sum W₁ₐ plus W₂ₐ, as can be seen in FIG. 1. The ratio W₁ₐ/P is an indication of the relative area of regions 1 with respect to that of regions 2. In some embodiments, W₁ₐ/P is greater than 0.8. In other embodiments, W₁ₐ/P ranges from 0.8 to 0.95, or from 0.8 to 0.9, or from 0.8 to 0.88, or from 0.82 to 0.88, or from 0.84 to 0.9, or from 0.85 to 0.87.

The inventors have observed that control over the arrangement and the shape (geometry) of the regions 2 can improve the efficiency of the LCF in allowing a maximum amount of radiation to pass through the film towards the photovoltaic surface, while concealing such surface from a viewer.

An optional land region can exist between either region 2 (140) and the light input surface (120) or region 1 (130) and the light output surface (110). This land region can be made of region 1 or region 2 material. In certain preferred embodiments, the land region is present and is made of region 1 material (see, e.g., FIG. 1B). For these preferred embodiments H₁>H₂. In other embodiments, another optional land region between region 1 and the light output surface (110) exists (see, e.g., FIG. 1C). For these embodiments the land region is made of region 2 material (H₁<H₂). In other embodiments there is no land present (H₁=H₂), which is the situation depicted in FIG. 1. In all embodiments, the effective height, “H”, is the lesser of H₁ and H₂.

The total height of the LCF is the greater of H₁ and H₂. In the embodiment shown in FIG. 1, H₁ is equal to H₂, but in other embodiments, H₁ may be different from H₂.

The LCF 100 includes an internal viewing angle ϕ_{I} defined by the geometry of alternating regions 1 (130) and regions 2 (140). A first interface (150) forms an interface angle θ₁ with a normal (160) to light output surface 110. As described herein, a line normal to a surface is meant to be a line perpendicular to the major plane of the surface, discounting any local variation in surface smoothness. In FIG. 1, θ₁ is shown as the angle between the normal (160) and a straight line extending from the first interface (150). The line extending from the first interface is shown as a dotted line and is labeled as 150′. In some embodiments, the interface angle θ₁ is not greater than 3 degrees.

Similarly, a second interface (170) forms an interface angle θ₂ with a normal 160 to light output surface 110. In FIG. 1, θ₂ is shown as the angle between the normal (160) and a straight line extending from the second interface (170). The line extending from the second interface is shown as a dotted line and is labeled as 170′. In some embodiments, the interface angle θ₂ is not greater than 3 degrees. In some embodiments, the LCF 100 is characterized by a slant angle θₛₗₐₙₜ. The slant angle is given by the absolute value of one-half the difference between θ₁ and θ₂. In the embodiment of FIG. 1, θ₁≠θ₂ due to the asymmetric geometry of alternating like regions. In other embodiments, θ₁=θ₂ (θₛₗₐₙₜ=0). In other embodiments, θ₁=−θ₂ (θₛₗₐₙₜ=absolute value of θ₁=absolute value of θ₂). In certain embodiments, 0≤θₛₗₐₙₜ≤50. In other embodiments θₛₗₐₙₜ ranges from 5 to 50, or form 10 to 50, or form 15 to 50, or form 20 to 50, or form 25 to 50, or form 30 to 50, or form 35 to 50, or form 40 to 50, or form 45 to 50, or from 5 to 45, or form 10 to 45, or form 15 to 45, or form 20 to 45, or form 25 to 45, or form 30 to 45, or form 35 to 45, or form 40 to 45, 5 to 40, or form 10 to 40, or form 15 to 40, or form 20 to 40, or form 25 to 40, or form 30 to 40, or form 35 to 40, or from 5 to 35, or form 10 to 35, or form 15 to 35, or form 20 to 35, or form 25 to 35, or form 30 to 35, or from 5 to 30, or form 10 to 30, or form 15 to 30, or form 20 to 30, or form 25 to 30, or from 5 to 25, or form 10 to 25, or form 15 to 25, or form 20 to 25, or from 5 to 20, or form 10 to 20, or form 15 to 20, or from 5 to 15, or form 10 to 15, or from 5 to 10.

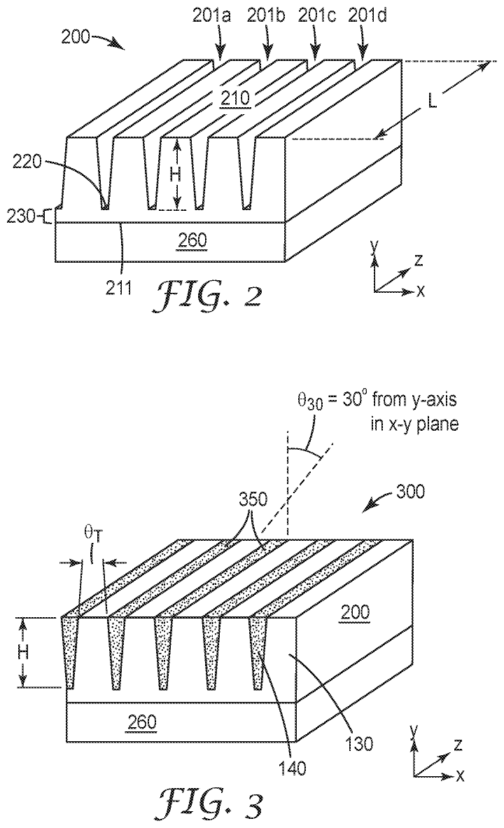

FIG. 2 shows a microstructured film article 200 including at least one microstructured surface 210, which can be used to make LCF. In one case, microstructured surface 210 can include a plurality of grooves 201a-201d. As shown in FIG. 2, a continuous land region 230 can be present between the base of the grooves 220 and the opposing surface 211 of the microstructured film article 200. In other cases grooves 220 can extend all the way through the microstructured film article 200 (i.e., there is no land region (not shown in the figure)). In one case, microstructured film article 200 can include a base substrate layer 260 which can be integrally formed with, or separately added to the microstructured film article 200 (e.g., by extrusion, cast-and-cure, or some other method). In one case the base substrate layer 260 may be of a different color than region 2 (140). In certain embodiments, the materials for the substrate layer 260 may include polycarbonate films or polyester films (such as PET), which may be selected to provide a matte finish or a glossy finish, with a matte finish being preferred in some embodiments. It should be noted that FIG. 2 is not drawn to scale. In some preferred embodiments, the length L of the grooves is substantially greater than the height H of the grooves. In some embodiments, the ratio of L/H is ≥20, or ≥100, or ≥1000.

FIG. 3 shows an LCF 300 based on the microstructured film article of FIG. 2, wherein grooves 201a-201d have been rendered mostly light absorbing over selective wavelength ranges by filling them with an appropriate absorbing material 350. Selective wavelength range absorbing material 350 in the shape of the recess of the (e.g. groove) microstructure is hereinafter referred to as region 2 (140). Regions 1 (130) and regions 2 (140) of LCF 300 have an included wall angle OT and an effective height H. Included wall angle θ_{T}, is the sum of θ₁ and θ₂, which are shown in FIG. 1. The effective height H is the lesser of H₁ and H₂, also shown in FIG. 1.

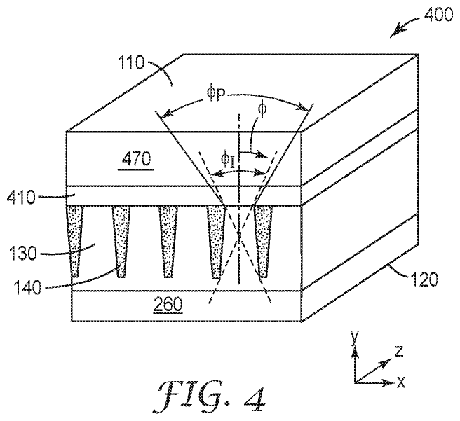

FIG. 4 shows an LCF 400 that further includes an optional adhesive layer 410 and release liner film 470. In the embodiment of FIG. 4, the LCF 400 includes light input surface 120 and light output surface 110 opposite light input surface 120. In another embodiment, not shown in FIG. 4, the surface 110 is the light input surface and the surface 120 is the light output surface. However, the particular embodiment shown in FIG. 4 (with surface 120 being the light input surface) can be more efficient due to total internal reflection (TIR) at the sidewall interface (e.g. interfaces 150 and 170, not shown in FIG. 4, but shown in FIG. 1) between regions 1 (130) and regions 2 (140). In one embodiment, which is not intended to be limiting, the adhesive 410 is comprised of an optically clear adhesive that is suitable for bonding to glass.

The internal viewing angle ϕ_{I}, shown in FIG. 1 is inversely proportional to the ratio H/W_{1b}. The larger the ratio the smaller the internal viewing angle. In some embodiments, the ratio H/W_{1b} ranges from 1.0 to 2.1. In other embodiments, the ratio H/W_{1b} ranges from 1.1 to 2.0, or from 1.2 to 1.7, or from 1.3 to 1.5. In some embodiments, the internal viewing angle ϕ_{I} is from 50° to 88°, or from 55° to 88°, or from 60° to 85°, or from 65° to 80°, or from 65° to 75°, or from 67° to 73°. The external viewing angle ϕ_{P} may be determined by applying Snell's law to the rays defining the internal viewing angle ϕ_{I}, using the refractive indices of: (a) the region 1 (130), N₁ shown in FIG. 1 and (b) the material the LCF 400 is immersed (typically air). For instance, (ϕ_{P}/2)=arcsin[N₁·sin(ϕ_{I}/2)] for LCF 400 immersed in air. LCFs can be made to have any desired external viewing cutoff angle ϕ_{P} by varying one or more of the parameters θ₁, θ₂ H, W₁ₐ, W₂ₐ, N₁, and the material the LCF 400 is immersed.

The angle ϕ shown in FIG. 4 represents an arbitrary measurement angle or viewing angle for an LCF 400. The angle ϕ is measured from a line drawn perpendicular to the light output surface (e.g. 160 in FIG. 1) and in a plane perpendicular to the longitudinal direction of the region 2 layer, shown in FIG. 2 as the xy plane. In FIGS. 2, 3, and 4, regions 2 are shown to have a symmetrical shape (θ₁=θ₂) for illustrative purposes. However, in some embodiments, the shape of the regions 2 is non symmetrical, having a θₛₗₐₙₜ different from zero, as shown in FIG. 1.

For LCFs that have regions 2 that are substantially absorbing in the visible range, the measured transmittance in the visible spectrum is maximum when the view angle ϕ=θₛₗₐₙₜ. In general, under those circumstances, as the view angle becomes farther removed from θₛₗₐₙₜ, the measured transmittance is decreased. Typically, introduction of TIR (total internal reflection) to the LCF tends to increase the measured transmittance compared to LCFs that show no TIR.

Light Control Films

As mentioned previously, in one aspect of the present disclosure, a light control film includes a plurality of alternating regions 1 (e.g. substantially transmissive) and regions 2 (e.g, selectively absorptive) adjacent to each other and located between a light input surface and a light output surface.

In certain embodiments, the LCF may be fabricated using a two-step process. First, a microstructure-bearing article (e.g. microstructured film article 200 in FIG. 2) can be prepared by a method including the steps of: (a) coating a radiation curable polymerizable material (region 1) onto a suitable substrate film (e.g. 0.005″ chemically primed PET film to promote improved adhesion between the resin and the PET film); (b) depositing the polymerizable material onto a master negative microstructured molding surface in an amount barely sufficient to fill the cavities of the master; (c) filling the cavities by moving a bead of the polymerizable material between a preformed base and the master, at least one of which is flexible; and (d) curing the polymerizable material before its removal from the master negative surface. The deposition temperature can range from ambient temperature to about 80° C. The grooves of the microstructured film article 200 in FIG. 2 are then filled using a spectrally selective absorbing material (region 2 material). Excess region 2 material can be wiped from the surface of region 1 material channels. The region 2 material is then cured using UV radiation, resulting in a light control film similar to that shown in FIG. 3.

In some cases, the polymerizable materials for the regions 1 matrix can comprise a (meth)acrylated urethane oligomer, (meth)acrylated epoxy oligomer, (meth)acrylated polyester oligomer, a (meth)acrylated phenolic oligomer, a (meth)acrylated acrylic oligomer, fluoropolymers, silicone polymers, thermoplastics such as polycarbonate, polyethylene, ethylene vinyl acetate (EVA) copolymers, polyethylene (alpha olefin) copolymers, and mixtures thereof. The polymerizable material can be a radiation curable polymeric resin, such as a UV curable resin. In certain preferred embodiments, the region 1 material is chosen from the reaction product of a polymerizable resin comprising a first and second polymerizable components selected from an aliphatic urethane diacrylate oligomer and a bisphenol-A ethoxylated diacrylate or bisphenol-A ethoxylated diacrylates; and a crosslinker having at least three (meth)acrylate groups.

In certain embodiments, the regions 2 may be formed from solvent-based materials, essentially solvent-free materials (less than 1% solvent), curable materials, or a combination thereof and may comprise materials selectively absorbing in certain spectral regions (e.g., visible region). Light absorbing materials for the region 2 can be any suitable material that functions to absorb or block light in at least a portion of the electromagnetic spectrum, preferably in the visible spectrum. In certain embodiments, the material for regions 2 is preferably substantially transmissive in non-visible regions, such as the infrared and/or ultraviolet regions. That is, in certain preferred embodiments, regions 2 have selective absorption in the visible region but are otherwise transparent in other spectral regions.

In some embodiments, absorptive materials for region 2 include materials selectively absorptive in the visible light and can be selected from a pigment, a dye, and combinations thereof. For instance, in some embodiments, the absorbing materials can include a colorant having other colors such as brown, black, cream, white, red, green, yellow, etc. Suitable pigments may be in particulate form or in other scattering format and may have a particle size less than 10 microns, for example 1 micron or less. The particles may, in some embodiments, have a mean particle size of less than 1 micron. In yet further embodiments, the selectively-absorbing material can be dispersed in a suitable binder. In some embodiments, larger particles, on the order of ≥0.1 times the width at the narrower width dimension of the regions 2 (W_{2b}), can aid with scattering light toward an underlying substrate such as a photovoltaic cell, and can obscure the cell from direct or indirect view. In some embodiments, the larger particles may be of a different color, to give a speckled appearance to the light control film.

Pigments can be selected so that radiation that contacts regions 2 can be either forward scattered or transmitted (rather than being absorbed) over particular wavelength regions of the electromagnetic spectrum and this helps to: 1) lower the amount of light absorbed by regions 2; and 2) increase the chance that the light reaches the photovoltaic surface thereby increasing efficacy of the LCF. In certain preferred embodiments, the pigments and dyes used in regions 2 are chosen from perylene pigments, mixed metal oxides (HMOs) such as those from cobalt, iron, chrome, tin, antimony, titanium, manganese, and aluminum. Different metal combinations produce a wide spectrum of colors ranging from black to brown to green, red, yellow, and blue. In some embodiments, the regions 2 substantially lack carbon black (i.e., have carbon black in a concentration of less than 0.5% with respect to the composition of the region 2 material).

The transmission properties of a light control film are influenced by various factors, such as, for example, the material composition of regions 1 and 2, the ratios H/W_{1b} and W₁ₐ/P, as well as the geometry of the regions 1 and 2 and their interfaces (e.g., θ₁ and θ₂). For example, for a fixed pitch, larger wall angles (θ_{T}, which is the sum of θ₁ plus θ₂) increase the width of the regions 2, thereby decreasing transmission at normal incidence. In general, smaller wall angles are preferred, such as less than 10 degrees, so that the transmission of light at normal incidence can be made as large as possible. In some embodiments, LCFs described herein have an included wall angle of not greater than 6°. In other embodiments, the included wall angle is not greater than 5°, such as up to 5°, 40°, 30°, 2°, 1° or 0.1°. As described herein, the included wall angle can be related to the interface angle for symmetric and asymmetric regions 2 (selectively absorptive). As such, in one aspect, each of interface angles (θ₁ and θ₂) can be, independently of each other, 3°, or not greater than 3°, for example not greater than 2.5°, 2°, 1°, or 0.1°. Smaller wall angles can form grooves (regions 2) having a relatively high aspect ratio (H/W_{1b}) at a smaller pitch P, and can provide a sharper image cutoff at smaller viewing angles.

As mentioned previously, in some embodiments, reflections at the interface of regions 1 and 2 can be controlled by mismatching the relative index of refraction of the light transmissive material and the index of refraction of the light absorbing material over at least a portion of the spectrum, for example the visible spectrum. In some cases, the index of refraction of the cured regions 1 (N₁) is greater than the index of refraction of the cured regions 2 (N₂) by not less than about 0.005.

In some embodiments, the LCFs may have an optional clear layer (or substrate) on either the light output or light input surfaces. Those substrates can be made from any clear material. In some embodiments, the substrates are made of a polymeric film such as polycarbonate (PC), polyethylene terephthalate (PET), and the like. In some embodiments, the substrate can have a refractive index from about 1.5 to about 1.67 or greater.

Yet in other embodiments, the clear layer mentioned in the preceding paragraph may be an optical film, such as an optical diffuser. An optical diffuser may assist in scattering light incident on the LCF, especially at high incident angles, into the light transmissive regions and toward the photovoltaic surface.

Yet in further embodiments, the LCFs may comprise an optional surface coating layer. For instance, the surface coating layer can be a diffusive material laminated to one of the layers of the light control film with a suitable optical adhesive. In some embodiments, the surface coating layer could include surface microstructures to modify the diffusion angles of light exiting the LCF construction. In some embodiments, the surface coating layer could be at least one of an antireflective coating or film, or at least one of an anti-glare coating or film.

In some embodiments, one or more of the layers of the light control film could include optional additives such as, for example, UV absorbers to reduce photo degradation of the regions 1 and 2, anti-microbial additives, and plasticizers to enhance flexibility and reduce cracking when the LCF construction is exposed to extreme temperature and humidity changes.

### EXEMPLARY EMBODIMENTS

1. A light control film comprising a structured layer comprising a plurality of regions 1 alternating with a plurality of regions 2,
   wherein the structured layer has a light input surface and a light output surface opposite the light input surface,
   wherein the plane of the light input surface defines a plane for the film,
   wherein at least one region 1 has a width at its base W_{1b}, a height H₁, and an index of refraction N₁,
   wherein at least one region 2 has a width at its base W_{2b}, a height H₂, and an index of refraction N₂,
   wherein the lesser of H₁ and H₂ is the effective height, H,
   wherein a first interface between the at least one region 1 and the at least one region 2 forms a first interface angle, θ₁, measured clockwise from a direction normal to the plane of the film,
   wherein a second interface between the at least one region 1 and the at least one region 2 forms a second interface angle, θ₂, measured counterclockwise from a direction normal to the plane of the film,
   wherein 1.0≤H/W_{1b}≤2.1,
   wherein the pitch, P, is the sum of W_{1b} and W_{2b},
   wherein the ratio W₁ₐ/P is greater than 0.8,
   wherein a film made of the same material, and having the same transmittance as the at least one region 1, has a 0° incidence angle transmittance of at least 70% in at least two of the following wavelength ranges:
      from 300 nm to 400 nm,
      from 400 nm to 750 nm,
      from 750 nm to 1500 nm,
   wherein a film made of the same material, and having the same transmittance as the at least one region 2, has a 0° incidence angle transmittance of at least 30% in one or two of the following wavelength ranges:
      from 300 nm to 400 nm,
      from 400 nm to 750 nm,
      from 750 nm to 1500 nm.
2. A light control film comprising a structured layer comprising a plurality of regions 1 alternating with a plurality of regions 2,
   wherein the structured layer has a light input surface and a light output surface opposite the light input surface,
   wherein the plane of the light input surface defines a plane for the film,
   wherein at least one region 1 has a width at its base W_{1b}, a height H₁, and an index of refraction N₁,
   wherein at least one region 2 has a width at its base W_{2b}, a height H₂, and an index of refraction N₂,
   wherein the lesser of H₁ and H₂ is the effective height, H,
   wherein a first interface between the at least one region 1 and the at least one region 2 forms a first interface angle, θ₁, measured clockwise from a direction normal to the plane of the film,
   wherein a second interface between the at least one region 1 and the at least one region 2 forms a second interface angle, θ₂, measured counterclockwise from a direction normal to the plane of the film,
   wherein 1.0≤H/W_{1b}≤2.1,
   wherein the pitch, P, is the sum of W_{1b} and W_{2b},
   wherein the ratio W₁ₐ/P is greater than 0.8,
   wherein the total 0° incidence angle transmittance of the film is at least 75% in at least one of the following wavelength ranges:
      from 300 nm to 400 nm,
      from 400 nm to 750 nm,
      from 750 nm to 1500 nm.
3. A light control film comprising a structured layer comprising a plurality of regions 1 alternating with a plurality of regions 2,
   wherein the structured layer has a light input surface and a light output surface opposite the light input surface,
   wherein the plane of the light input surface defines a plane for the film,
   wherein at least one region 1 has a width at its base W_{1b}, a height H₁, and an index of refraction N₁,
   wherein at least one region 2 has a width at its base W_{2b}, a height H₂, and an index of refraction N₂,
   wherein the lesser of H₁ and H₂ is the effective height, H,
   wherein a first interface between the at least one region 1 and the at least one region 2 forms a first interface angle, θ₁, measured clockwise from a direction normal to the plane of the film,
   wherein a second interface between the at least one region 1 and the at least one region 2 forms a second interface angle, θ₂, measured counterclockwise from a direction normal to the plane of the film,
   wherein 1.0≤H/W_{1b}≤2.1,
   wherein the pitch, P, is the sum of W_{1b} and W_{2b},
   wherein the ratio W₁ₐ/P is greater than 0.8.
4. A light control film comprising a structured layer comprising a plurality of regions 1 alternating with a plurality of regions 2,
   wherein the structured layer has a light input surface and a light output surface opposite the light input surface,
   wherein the plane of the light input surface defines a plane for the film,
   wherein at least one region 1 has a width at its base W_{1b}, a height H₁, and an index of refraction N₁,
   wherein at least one region 2 has a width at its base W_{2b}, a height H₂, and an index of refraction N₂,
   wherein the lesser of H₁ and H₂ is the effective height, H,
   wherein a first interface between the at least one region 1 and the at least one region 2 forms a first interface angle, θ1, measured clockwise from a direction normal to the plane of the film,
   wherein a second interface between the at least one region 1 and the at least one region 2 forms a second interface angle, θ₂, measured counterclockwise from a direction normal to the plane of the film,
   wherein 1.0≤H/W_{1b}≤2.1,
   wherein the pitch, P, is the sum of W_{1b} and W_{2b},
   wherein the ratio W₁ₐ/P is greater than 0.8,
   wherein N₁−N₂ is not less than 0.005,
   wherein a film made of the same material, and having the same transmittance as the at least one region 1, has a 0° incidence angle transmittance of at least 70% in at least two of the following wavelength ranges:
      from 300 nm to 400 nm,
      from 400 nm to 750 nm,
      from 750 nm to 1500 nm,
   wherein a film made of the same material, and having the same transmittance as the at least one region 2, has a 0° incidence angle transmittance of at least 30% in one or two of the following wavelength ranges:
      from 300 nm to 400 nm,
      from 400 nm to 750 nm,
      from 750 nm to 1500 nm.
5. A light control film comprising a structured layer comprising a plurality of regions 1 alternating with a plurality of regions 2,
   wherein the structured layer has a light input surface and a light output surface opposite the light input surface,
   wherein the plane of the light input surface defines a plane for the film,
   wherein at least one region 1 has a width at its base W_{1b}, a height H₁, and an index of refraction N₁,
   wherein at least one region 2 has a width at its base W_{2b}, a height H₂, and an index of refraction N₂,
   wherein the lesser of H₁ and H₂ is the effective height, H,
   wherein a first interface between the at least one region 1 and the at least one region 2 forms a first interface angle, θ₁, measured clockwise from a direction normal to the plane of the film,
   wherein a second interface between the at least one region 1 and the at least one region 2 forms a second interface angle, θ₂, measured counterclockwise from a direction normal to the plane of the film,
   wherein 1.0≤H/W_{2b}≤2.1,
   wherein the pitch, P, is the sum of W_{1b} and W_{2b},
   wherein the ratio W₁ₐ/P is greater than 0.8,
   wherein N₁−N₂ is not less than 0.005,
   wherein the total 0° incidence angle transmittance of the film is at least 75% in at least one of the following wavelength ranges:
      from 300 nm to 400 nm,
      from 400 nm to 750 nm,
      from 750 to 1500 nm.
6. A light control film comprising a structured layer comprising a plurality of regions 1 alternating with a plurality of regions 2,
   wherein the structured layer has a light input surface and a light output surface opposite the light input surface,
   wherein the plane of the light input surface defines a plane for the film,
   wherein at least one region 1 has a width at its base W_{1b}, a height H₁, and an index of refraction N₁,
   wherein at least one region 2 has a width at its base W_{2b}, a height H₂, and an index of refraction N₂,
   wherein the lesser of H₁ and H₂ is the effective height, H,
   wherein a first interface between the at least one region 1 and the at least one region 2 forms a first interface angle, θ₁, measured clockwise from a direction normal to the plane of the film,
   wherein a second interface between the at least one region 1 and the at least one region 2 forms a second interface angle, θ₂, measured counterclockwise from a direction normal to the plane of the film,
   wherein 1.0≤H/W_{1b}≤2.1,
   wherein the pitch, P, is the sum of W_{1b} and W_{2b},
   wherein the ratio W₁ₐ/P is greater than 0.8,
   wherein N₁−N₂ is not less than 0.005.
7. A light control film comprising a structured layer comprising a plurality of regions 1 alternating with a plurality of regions 2,
   wherein the structured layer has a light input surface and a light output surface opposite the light input surface,
   wherein the plane of the light input surface defines a plane for the film,
   wherein at least one region 1 has a width at its base W_{1b}, a height H₁, and an index of refraction N₁,
   wherein at least one region 2 has a width at its base W_{2b}, a height H₂, and an index of refraction N₂,
   wherein the lesser of H₁ and H₂ is the effective height, H,
   wherein a first interface between the at least one region 1 and the at least one region 2 forms a first interface angle, θ₁, measured clockwise from a direction normal to the plane of the film,
   wherein a second interface between the at least one region 1 and the at least one region 2 forms a second interface angle, θ₂, measured clockwise from a direction normal to the plane of the film,
   wherein 1.0≤H/W_{1b}≤2.1,
   wherein the pitch, P, is the sum of W_{1b} and W_{2b},
   wherein the ratio W₁ₐ/P is greater than 0.8,
   wherein θₛₗₐₙₜ is defined as the absolute value of [(θ₂ minus θ₁)/2],
   wherein 0≤θₛₗₐₙₜ≤50,
   wherein a film made of the same material, and having the same transmittance as the at least one region 1, has a 0° incidence angle transmittance of at least 70% in at least two of the following wavelength ranges:
      from 300 nm to 400 nm,
      from 400 nm to 750 nm,
      from 750 nm to 1500 nm,
   wherein a film made of the same material, and having the same transmittance as the at least one region 2, has a 0° incidence angle transmittance of at least 30% in one or two of the following wavelength ranges:
      from 300 nm to 400 nm,
      from 400 nm to 750 nm,
      from 750 nm to 1500 nm.
8. A light control film comprising a structured layer comprising a plurality of regions 1 alternating with a plurality of regions 2,
   wherein the structured layer has a light input surface and a light output surface opposite the light input surface,
   wherein the plane of the light input surface defines a plane for the film,
   wherein at least one region 1 has a width at its base W_{1b}, a height H₁, and an index of refraction N₁,
   wherein at least one region 2 has a width at its base W_{2b}, a height H₂, and an index of refraction N₂,
   wherein the lesser of H₁ and H₂ is the effective height, H,
   wherein a first interface between the at least one region 1 and the at least one region 2 forms a first interface angle, θ₁, measured clockwise from a direction normal to the plane of the film,
   wherein a second interface between the at least one region 1 and the at least one region 2 forms a second interface angle, θ₂, measured counterclockwise from a direction normal to the plane of the film,
   wherein 1.0≤H/W_{1b}≤2.1,
   wherein the pitch, P, is the sum of W_{1b} and W_{2b},
   wherein the ratio W₁ₐ/P is greater than 0.8,
   wherein θₛₗₐₙₜ is defined as the absolute value of [(θ₂ minus θ₁)/2],
   wherein 0≤θₛₗₐₙₜ≤50,
   wherein the total 0° incidence angle transmittance of the film is at least 75% in at least one of the following wavelength ranges:
      from 300 nm to 400 nm,
      from 400 nm to 750 nm,
      from 750 nm to 1500 nm.
9. A light control film comprising a structured layer comprising a plurality of regions 1 alternating with a plurality of regions 2,
   wherein the structured layer has a light input surface and a light output surface opposite the light input surface,
   wherein the plane of the light input surface defines a plane for the film,
   wherein at least one region 1 has a width at its base W_{1b}, a height H₁, and an index of refraction N₁,
   wherein at least one region 2 has a width at its base W_{2b}, a height H₂, and an index of refraction N₂,
   wherein the lesser of H₁ and H₂ is the effective height, H,
   wherein a first interface between the at least one region 1 and the at least one region 2 forms a first interface angle, θ₁, measured clockwise from a direction normal to the plane of the film,
   wherein a second interface between the at least one region 1 and the at least one region 2 forms a second interface angle, θ₂, measured counterclockwise from a direction normal to the plane of the film,
   wherein 1.0≤H/W_{1b}≤2.1,
   wherein the pitch, P, is the sum of W_{1b} and W_{2b},
   wherein the ratio W₁ₐ/P is greater than 0.8,
   wherein θₛₗₐₙₜ is defined as the absolute value of [(θ₂ minus θ₁)/2],
   wherein 0≤θₛₗₐₙₜ≤50.
10. A light control film comprising a structured layer comprising a plurality of regions 1 alternating with a plurality of regions 2,
   wherein the structured layer has a light input surface and a light output surface opposite the light input surface,
   wherein the plane of the light input surface defines a plane for the film,
   wherein at least one region 1 has a width at its base W_{1b}, a height H₁, and an index of refraction N₁,
   wherein at least one region 2 has a width at its base W_{2b}, a height H₂, and an index of refraction N₂,
   wherein the lesser of H₁ and H₂ is the effective height, H,
   wherein a first interface between the at least one region 1 and the at least one region 2 forms a first interface angle, θ₁, measured clockwise from a direction normal to the plane of the film,
   wherein a second interface between the at least one region 1 and the at least one region 2 forms a second interface angle, θ₂, measured counterclockwise from a direction normal to the plane of the film,
   wherein the film has an internal viewing angle, ϕ_{I},
   wherein 50°≤ϕ_{I}≤88°,
   wherein the pitch, P, is the sum of W_{1b} and W_{1b},
   wherein the ratio W₁ₐ/P is greater than 0.8,
   wherein a film made of the same material, and having the same transmittance as the at least one region 1, has a 0° incidence angle transmittance of at least 70% in at least two of the following wavelength ranges:
      from 300 nm to 400 nm,
      from 400 nm to 750 nm,
      from 750 nm to 1500 nm,
   wherein a film made of the same material, and having the same transmittance as the at least one region 2, has a 0° incidence angle transmittance of at least 30% in one or two of the following wavelength ranges:
      from 300 nm to 400 nm,
      from 400 nm to 750 nm,
      from 750 nm to 1500 nm.
11. A light control film comprising a structured layer comprising a plurality of regions 1 alternating with a plurality of regions 2,
   wherein the structured layer has a light input surface and a light output surface opposite the light input surface,
   wherein the plane of the light input surface defines a plane for the film,
   wherein at least one region 1 has a width at its base W_{1b}, a height H₁, and an index of refraction N₁,
   wherein at least one region 2 has a width at its base W_{2b}, a height H₂, and an index of refraction N₂,
   wherein the lesser of H₁ and H₂ is the effective height, H,
   wherein a first interface between the at least one region 1 and the at least one region 2 forms a first interface angle, θ₁, measured clockwise from a direction normal to the plane of the film,
   wherein a second interface between the at least one region 1 and the at least one region 2 forms a second interface angle, θ₂, measured counterclockwise from a direction normal to the plane of the film,
   wherein the film has an internal viewing angle, ϕ_{I},
   wherein 50°≤ϕ_{I}≤88°,
   wherein the pitch, P, is the sum of W_{1b} and W_{2b},
   wherein the ratio W₁ₐ/P is greater than 0.8,
   wherein a the total 0° incidence angle transmittance of the film is at least 75% in at least one of the following wavelength ranges:
      from 300 nm to 400 nm,
      from 400 nm to 750 nm,
      from 750 nm to 1500 nm.
12. A light control film comprising a structured layer comprising a plurality of regions 1 alternating with a plurality of regions 2,
   wherein the structured layer has a light input surface and a light output surface opposite the light input surface,
   wherein the plane of the light input surface defines a plane for the film,
   wherein at least one region 1 has a width at its base W_{1b}, a height H₁, and an index of refraction N₁,
   wherein at least one region 2 has a width at its base W_{2b}, a height H₂, and an index of refraction N₂,
   wherein the lesser of H₁ and H₂ is the effective height, H,
   wherein a first interface between the at least one region 1 and the at least one region 2 forms a first interface angle, θ₁, measured clockwise from a direction normal to the plane of the film,
   wherein a second interface between the at least one region 1 and the at least one region 2 forms a second interface angle, θ₂, measured counterclockwise from a direction normal to the plane of the film,
   wherein the film has an internal viewing angle, ϕ_{I},
   wherein 50°≤ϕ_{I}≤88°,
   wherein the pitch, P, is the sum of W_{1b} and W_{2b},
   wherein the ratio W₁ₐ/P is greater than 0.8.
13. A light control film comprising a structured layer comprising a plurality of regions 1 alternating with a plurality of regions 2,
   wherein the structured layer has a light input surface and a light output surface opposite the light input surface,
   wherein the plane of the light input surface defines a plane for the film,
   wherein at least one region 1 has a width at its base W_{1b}, a height H₁, and an index of refraction N₁,
   wherein at least one region 2 has a width at its base W_{2b}, a height H₂, and an index of refraction N₂,
   wherein the lesser of H₁ and H₂ is the effective height, H,
   wherein a first interface between the at least one region 1 and the at least one region 2 forms a first interface angle, θ₁, measured clockwise from a direction normal to the plane of the film,
   wherein a second interface between the at least one region 1 and the at least one region 2 forms a second interface angle, θ₂, measured counterclockwise from a direction normal to the plane of the film,
   wherein the film has an internal viewing angle, ϕ_{I},
   wherein 50°≤ϕ_{I}≤88°,
   wherein the pitch, P, is the sum of W_{1b}, and W_{2b},
   wherein the ratio W₁ₐ/P is greater than 0.8,
   wherein N₁−N₂ is not less than 0.005,
   wherein a film made of the same material, and having the same transmittance as the at least one region 1, has a 0° incidence angle transmittance of at least 70% in at least two of the following wavelength ranges:
      from 300 nm to 400 nm,
      from 400 nm to 750 nm,
      from 750 nm to 1500 nm,
   wherein a film made of the same material, and having the same transmittance as the at least one region 2, has a 0° incidence angle transmittance of at least 30% in one or two of the following wavelength ranges:
      from 300 nm to 400 nm,
      from 400 nm to 750 nm,
      from 750 nm to 1500 nm.
14. A light control film comprising a structured layer comprising a plurality of regions 1 alternating with a plurality of regions 2,
   wherein the structured layer has a light input surface and a light output surface opposite the light input surface,
   wherein the plane of the light input surface defines a plane for the film,
   wherein at least one region 1 has a width at its base W_{1b}, a height H₁, and an index of refraction N₁,
   wherein at least one region 2 has a width at its base W_{2b}, a height H₂, and an index of refraction N₂,
   wherein the lesser of H₁ and H₂ is the effective height, H,
   wherein a first interface between the at least one region 1 and the at least one region 2 forms a first interface angle, θ₁, measured clockwise from a direction normal to the plane of the film,
   wherein a second interface between the at least one region 1 and the at least one region 2 forms a second interface angle, θ₂, measured counterclockwise from a direction normal to the plane of the film,
   wherein the film has an internal viewing angle, ϕ_{I},
   wherein 50°≤ϕ_{I}≤88°,
   wherein the pitch, P, is the sum of W_{1b}, and W_{2b},
   wherein the ratio W₁ₐ/P is greater than 0.8,
   wherein N₁−N₂ is not less than 0.005,
   wherein a the total 0° incidence angle transmittance of the film is at least 75% in at least one of the following wavelength ranges:
      from 300 nm to 400 nm,
      from 400 nm to 750 nm,
      from 750 nm to 1500 nm.
15. A light control film comprising a structured layer comprising a plurality of regions 1 alternating with a plurality of regions 2,
   wherein the structured layer has a light input surface and a light output surface opposite the light input surface,
   wherein the plane of the light input surface defines a plane for the film,
   wherein at least one region 1 has a width at its base W_{1b}, a height H₁, and an index of refraction N₁,
   wherein at least one region 2 has a width at its base W_{2b}, a height H₂, and an index of refraction N₂,
   wherein the lesser of H₁ and H₂ is the effective height, H,
   wherein a first interface between the at least one region 1 and the at least one region 2 forms a first interface angle, θ₁, measured clockwise from a direction normal to the plane of the film,
   wherein a second interface between the at least one region 1 and the at least one region 2 forms a second interface angle, θ₂, measured counterclockwise from a direction normal to the plane of the film,
   wherein the film has an internal viewing angle, ϕ_{I},
   wherein 50°≤ϕ_{I}≤88°,
   wherein the pitch, P, is the sum of W_{1b} and W_{2b},
   wherein the ratio W₁ₐ/P is greater than 0.8,
   wherein N₁−N₂ is not less than 0.005.
16. A light control film comprising a structured layer comprising a plurality of regions 1 alternating with a plurality of regions 2,
   wherein the structured layer has a light input surface and a light output surface opposite the light input surface,
   wherein the plane of the light input surface defines a plane for the film,
   wherein at least one region 1 has a width at its base W_{1b}, a height H₁, and an index of refraction N₁,
   wherein at least one region 2 has a width at its base W_{2b}, a height H₂, and an index of refraction N₂,
   wherein the lesser of H₁ and H₂ is the effective height, H,
   wherein a first interface between the at least one region 1 and the at least one region 2 forms a first interface angle, θ₁, measured clockwise from a direction normal to the plane of the film,
   wherein a second interface between the at least one region 1 and the at least one region 2 forms a second interface angle, θ₂, measured counterclockwise from a direction normal to the plane of the film,
   wherein the film has an internal viewing angle, ϕ_{I},
   wherein 50°≤ϕ_{I}≤88°,
   wherein the pitch, P, is the sum of W_{1b}, and W_{2b},
   wherein the ratio W₁ₐ/P is greater than 0.8,
   wherein θₛₗₐₙₜ is defined as the absolute value of [(θ₂ minus θ₁)/2],
   wherein 0≤θₛₗₐₙₜ≤50,
   wherein a film made of the same material, and having the same transmittance as the at least one region 1, has a 0° incidence angle transmittance of at least 70% in at least two of the following wavelength ranges:
      from 300 nm to 400 nm,
      from 400 nm to 750 nm,
      from 750 nm to 1500 nm,
   wherein a film made of the same material, and having the same transmittance as the at least one region 2, has a 0° incidence angle transmittance of at least 30% in one or two of the following wavelength ranges:
      from 300 nm to 400 nm,
      from 400 nm to 750 nm,
      from 750 nm to 1500 nm.
17. A light control film comprising a structured layer comprising a plurality of regions 1 alternating with a plurality of regions 2,
   wherein the structured layer has a light input surface and a light output surface opposite the light input surface,
   wherein the plane of the light input surface defines a plane for the film,
   wherein at least one region 1 has a width at its base W_{1b}, a height H₁, and an index of refraction N₁,
   wherein at least one region 2 has a width at its base W_{2b}, a height H₂, and an index of refraction N₂,
   wherein the lesser of H₁ and H₂ is the effective height, H,
   wherein a first interface between the at least one region 1 and the at least one region 2 forms a first interface angle, θ₁, measured clockwise from a direction normal to the plane of the film,
   wherein a second interface between the at least one region 1 and the at least one region 2 forms a second interface angle, θ₂, measured counterclockwise from a direction normal to the plane of the film,
   wherein the film has an internal viewing angle, ϕ_{I},
   wherein 50°≤ϕ₁≤88°,
   wherein the pitch, P, is the sum of W_{1b} and W_{2b},
   wherein the ratio W₁ₐ/P is greater than 0.8,
   wherein θₛₗₐₙₜ is defined as the absolute value of [(θ₂ minus θ₁)/2],
   wherein 0≤θₛₗₐₙₜ≤50,
   wherein a the total 0° incidence angle transmittance of the film is at least 75% in at least one of the following wavelength ranges:
      from 300 nm to 400 nm,
      from 400 nm to 750 nm,
      from 750 nm to 1500 nm.
18. A light control film comprising a structured layer comprising a plurality of regions 1 alternating with a plurality of regions 2,
   wherein the structured layer has a light input surface and a light output surface opposite the light input surface,
   wherein the plane of the light input surface defines a plane for the film,
   wherein at least one region 1 has a width at its base W_{1b}, a height H₁, and an index of refraction N₁,
   wherein at least one region 2 has a width at its base W_{2b}, a height H₂, and an index of refraction N₂,
   wherein the lesser of H₁ and H₂ is the effective height, H,
   wherein a first interface between the at least one region 1 and the at least one region 2 forms a first interface angle, θ₁, measured clockwise from a direction normal to the plane of the film,
   wherein a second interface between the at least one region 1 and the at least one region 2 forms a second interface angle, θ₂, measured counterclockwise from a direction normal to the plane of the film,
   wherein the film has an internal viewing angle, ϕ_{I},
   wherein 50°≤ϕ_{I}≤88°,
   wherein the pitch, P, is the sum of W_{1b} and W_{2b},
   wherein the ratio W₁ₐ/P is greater than 0.8,
   wherein θₛₗₐₙₜ is defined as the absolute value of [(θ₂ minus θ₁)/2],
   wherein 0≤θₛₗₐₙₜ≤50.
19. A light control film comprising a structured layer comprising a plurality of regions 1 alternating with a plurality of regions 2,
   wherein the structured layer has a light input surface and a light output surface opposite the light input surface,
   wherein the plane of the light input surface defines a plane for the film,
   wherein at least one region 1 has a width at its base W_{1b}, a height H₁, and an index of refraction N₁,
   wherein at least one region 2 has a width at its base W_{2b}, a height H₂, and an index of refraction N₂,
   wherein the lesser of H₁ and H₂ is the effective height, H,
   wherein a first interface between the at least one region 1 and the at least one region 2 forms a first interface angle, θ₁, measured clockwise from a direction normal to the plane of the film,
   wherein a second interface between the at least one region 1 and the at least one region 2 forms a second interface angle, θ₂, measured counterclockwise from a direction normal to the plane of the film,
   wherein the 30° incidence angle transmittance of the film is at least 30% in at least one of the following wavelength ranges:
      from 300 nm to 400 nm,
      from 400 nm to 750 nm,
      from 750 nm to 1500 nm.
20. A light control film comprising a structured layer comprising a plurality of regions 1 alternating with a plurality of regions 2,
   wherein the structured layer has a light input surface and a light output surface opposite the light input surface,
   wherein the plane of the light input surface defines a plane for the film,
   wherein at least one region 1 has a width at its base W_{1b}, a height H₁, and an index of refraction N₁,
   wherein at least one region 2 has a width at its base W_{2b}, a height H₂, and an index of refraction N₂,
   wherein the lesser of H₁ and H₂ is the effective height, H,
   wherein a first interface between the at least one region 1 and the at least one region 2 forms a first interface angle, θ₁, measured clockwise from a direction normal to the plane of the film,
   wherein a second interface between the at least one region 1 and the at least one region 2 forms a second interface angle, θ₂, measured counterclockwise from a direction normal to the plane of the film,
   wherein 1.0≤H/W_{1b}≤2.1,
   wherein the pitch, P, is the sum of W_{1b} and W_{2b},
   wherein the ratio W₁ₐ/P is greater than 0.8,
   wherein the 30° incidence angle transmittance of the film is at least 30% in at least one of the following wavelength ranges:
      from 300 nm to 400 nm,
      from 400 nm to 750 nm,
      from 750 nm to 1500 nm.
21. A light control film comprising a structured layer comprising a plurality of regions 1 alternating with a plurality of regions 2,
   wherein the structured layer has a light input surface and a light output surface opposite the light input surface,
   wherein the plane of the light input surface defines a plane for the film,
   wherein at least one region 1 has a width at its base W_{1b}, a height H₁, and an index of refraction N₁,
   wherein at least one region 2 has a width at its base W_{2b}, a height H₂, and an index of refraction N₂,
   wherein the lesser of H₁ and H₂ is the effective height, H,
   wherein a first interface between the at least one region 1 and the at least one region 2 forms a first interface angle, θ₁, measured clockwise from a direction normal to the plane of the film,
   wherein a second interface between the at least one region 1 and the at least one region 2 forms a second interface angle, θ₂, measured counterclockwise from a direction normal to the plane of the film,
   wherein 1.0≤H/W_{1b}≤2.1,
   wherein the pitch, P, is the sum of W_{1b} and W_{2b},
   wherein the ratio W₁ₐ/P is greater than 0.8,
   wherein N₁−N₂ is not less than 0.005,
   wherein the 30° incidence angle transmittance of the film is at least 30% in at least one of the following wavelength ranges:
      from 300 nm to 400 nm,
      from 400 nm to 750 nm,
      from 750 nm to 1500 nm.
22. A light control film comprising a structured layer comprising a plurality of regions 1 alternating with a plurality of regions 2,
   wherein the structured layer has a light input surface and a light output surface opposite the light input surface,
   wherein the plane of the light input surface defines a plane for the film,
   wherein at least one region 1 has a width at its base W_{1b}, a height H₁, and an index of refraction N₁,
   wherein at least one region 2 has a width at its base W_{2b}, a height H₂, and an index of refraction N₂,
   wherein the lesser of H₁ and H₂ is the effective height, H,
   wherein a first interface between the at least one region 1 and the at least one region 2 forms a first interface angle, θ₁, measured clockwise from a direction normal to the plane of the film,
   wherein a second interface between the at least one region 1 and the at least one region 2 forms a second interface angle, θ₂, measured counterclockwise from a direction normal to the plane of the film,
   wherein the film has an internal viewing angle, ϕ_{I},
   wherein 50°≤ϕ_{I}≤88°,
   wherein the pitch, P, is the sum of W_{1b} and W_{2b},
   wherein the ratio W₁ₐ/P is greater than 0.8,
   wherein the 30° incidence angle transmittance of the film is at least 30% in at least one of the following wavelength ranges:
      from 300 nm to 400 nm,
      from 400 nm to 750 nm,
      from 750 nm to 1500 nm.
23. A light control film comprising a structured layer comprising a plurality of regions 1 alternating with a plurality of regions 2,
   wherein the structured layer has a light input surface and a light output surface opposite the light input surface,
   wherein the plane of the light input surface defines a plane for the film,
   wherein at least one region 1 has a width at its base W_{1b}, a height H₁, and an index of refraction N₁,
   wherein at least one region 2 has a width at its base W_{2b}, a height H₂, and an index of refraction N₂,
   wherein the lesser of H₁ and H₂ is the effective height, H,
   wherein a first interface between the at least one region 1 and the at least one region 2 forms a first interface angle, θ₁, measured clockwise from a direction normal to the plane of the film,
   wherein a second interface between the at least one region 1 and the at least one region 2 forms a second interface angle, θ₂, measured counterclockwise from a direction normal to the plane of the film,
   wherein θₛₗₐₙₜ is defined as the absolute value of [(θ₂ minus θ₁)/2],
   wherein 0≤θₛₗₐₙₜ≤50,
   wherein the pitch, P, is the sum of W_{1b}, and W_{2b},
   wherein the ratio W₁ₐ/P is greater than 0.8,
   wherein N₁−N₂ is not less than 0.005,
   wherein the 30° incidence angle transmittance of the film is at least 30% in at least one of the following wavelength ranges:
      from 300 nm to 400 nm,
      from 400 nm to 750 nm,
      from 750 nm to 1500 nm.
24. A light control film comprising a structured layer comprising a plurality of regions 1 alternating with a plurality of regions 2,
   wherein the structured layer has a light input surface and a light output surface opposite the light input surface,
   wherein the plane of the light input surface defines a plane for the film,
   wherein at least one region 1 has a width at its base W_{1b}, a height H₁, and an index of refraction N₁,
   wherein at least one region 2 has a width at its base W_{2b}, a height H₂, and an index of refraction N₂,
   wherein the lesser of H₁ and H₂ is the effective height, H,
   wherein a first interface between the at least one region 1 and the at least one region 2 forms a first interface angle, θ₁, measured clockwise from a direction normal to the plane of the film,
   wherein a second interface between the at least one region 1 and the at least one region 2 forms a second interface angle, θ₂, measured counterclockwise from a direction normal to the plane of the film,
   wherein the film has an internal viewing angle, ϕ_{I},
   wherein 50°≤ϕ_{I}≤88°,
   wherein θₛₗₐₙₜ is defined as the absolute value of [(θ₂ minus θ₁)/2],
   wherein 0≤θₛₗₐₙₜ≤50,
   wherein the pitch, P, is the sum of W_{1b} and W_{2b},
   wherein the ratio W₁ₐ/P is greater than 0.8,
   wherein N₁−N₂ is not less than 0.005,
   wherein the 30° incidence angle transmittance of the film is at least 30% in at least one of the following wavelength ranges:
      from 300 nm to 400 nm,
      from 400 nm to 750 nm,
      from 750 nm to 1500 nm.
25. The light control film according to any of the preceding embodiments, wherein the total 0° incidence angle transmittance of the film is at least 75% in at least one of the following wavelength ranges:
   from 300 nm to 400 nm,
   from 400 nm to 750 nm,
   from 750 nm to 1500 nm.
26. The light control film according to any of the preceding embodiments, wherein the total 0° incidence angle transmittance of the film is at least 80% in at least one of the following wavelength ranges:
   from 300 nm to 400 nm,
   from 400 nm to 750 nm,
   from 750 nm to 1500 nm.
27. The light control film according to any of the preceding embodiments, wherein the total 0° incidence angle transmittance of the film is at least 90% in at least one of the following wavelength ranges:
   from 300 nm to 400 nm,
   from 400 nm to 750 nm,
   from 750 nm to 1500 nm.
28. The light control film according to any of the preceding embodiments, wherein N₁−N₂ is not less than 0.005.
29. The light control film according to any of the preceding embodiments, wherein the film has an internal viewing angle, ϕ_{I}, and wherein 50°≤ϕ_{I}≤88°.
30. The light control film according to any of the preceding embodiments, wherein the film has an internal viewing angle, ϕ_{I}, and wherein 55°≤ϕ_{I}≤88°.
31. The light control film according to any of the preceding embodiments, wherein the film has an internal viewing angle, ϕ_{I}, and wherein 60°≤ϕ_{I}≤85°.
32. The light control film according to any of the preceding embodiments, wherein the film has an internal viewing angle, ϕ_{I}, and wherein 65°≤ϕ_{I}≤80°.
33. The light control film according to any of the preceding embodiments, wherein the film has an internal viewing angle, ϕ_{I}, and wherein 65°≤ϕ_{I}>75°.
34. The light control film according to any of the preceding embodiments, wherein the film has an internal viewing angle, ϕ_{I}, and wherein 67°≤ϕ_{I}≤73°.
35. The light control film according to any of the preceding embodiments, wherein the first interface angle, θ_{1,} is 3° or less.
36. The light control film according to any of the preceding embodiments, wherein the second interface angle, θ₂, is 3° or less.
37. The light control film according to any of the preceding embodiments, wherein first interface angle, θ₁, is 3° or less, wherein second interface angle, θ₂, is 3° or less, and wherein the first interface angle, θ₁, is substantially similar to second interface angle θ_{2.}
38. The light control film according to any of the preceding embodiments, wherein H/W_{1b} ranges from 1.0 to 2.1.
39. The light control film according to any of the preceding embodiments, wherein H/W_{1b} ranges from 1.2 to 2.0.
40. The light control film according to any of the preceding embodiments, wherein H/W_{1b} ranges from 1.2 to 1.7.
41. The light control film according to any of the preceding embodiments, wherein H/W_{1b} ranges from 1.3 to 1.5.
42. The light control film according to any of the preceding embodiments, wherein W₁ₐ/P ranges from 0.8 to 0.95.
43. The light control film according to any of the preceding embodiments, wherein W₁ₐ/P ranges from 0.8 to 0.9.
44. The light control film according to any of the preceding embodiments, wherein W₁ₐ/P ranges from 0.8 to 0.88.
45. The light control film according to any of the preceding embodiments, wherein W₁ₐ/P ranges from 0.82 to 0.88.
46. The light control film according to any of the preceding embodiments, wherein θₛₗₐₙₜ is defined as the absolute value of [(θ₂ minus θ₁/2], and wherein 3°≤θₛₗₐₙₜ≤30°.
47. The light control film according to any of the preceding embodiments, wherein θₛₗₐₙₜ is defined as the absolute value of [θ₂ minus θ₁)/2], and wherein 3°≤θₛₗₐₙₜ≤15°.
48. The light control film according to any of the preceding embodiments, wherein a film made of the same material, and having the same transmittance as the at least one region 1, has a 0° incidence angle transmittance of at least 70% in at least two of the following wavelength ranges:
   from 300 nm to 400 nm,
   from 400 nm to 750 nm,
   from 750 nm to 1500 nm,
wherein a film made of the same material, and having the same transmittance as the at least one region 2, has a 0° incidence angle transmittance of at least 30% in one or two of the following wavelength ranges:
   from 300 nm to 400 nm,
   from 400 nm to 750 nm,
   from 750 nm to 1500 nm.
49. The light control film according to any of the preceding embodiments, wherein a film made of the same material, and having the same transmittance as the at least one region 1, has a 0° incidence angle transmittance of at least 80% in at least two of the following wavelength ranges:
   from 300 nm to 400 nm,
   from 400 nm to 750 nm,
   from 750 nm to 1500 nm,
wherein a film made of the same material, and having the same transmittance as the at least one region 2, has a 0° incidence angle transmittance of at least 50% in one or two of the following wavelength ranges:
   from 300 nm to 400 nm,
   from 400 nm to 750 nm,
   from 750 nm to 1500 nm.
50. The light control film according to any of the preceding embodiments, wherein solar light incident in a direction perpendicular to the light input surface exits the light output surface at greater than 90% of the maximum brightness measured at any angle less than 30° from the direction perpendicular to the light output surface as measured over a wavelength range from about 300 nm to 1500 nm.
51. The light control film according to any of the preceding embodiments, wherein solar light incident in a direction perpendicular to the light input surface exits the light output surface at greater than 80% of the maximum brightness measured at any angle less than 30° from the direction perpendicular to the light output surface as measured over a wavelength range from about 300 nm to 1500 nm.
52. The light control film according to any of the preceding embodiments, wherein solar light incident in a direction perpendicular to the light input surface exits the light output surface at greater than 70% of the maximum brightness measured at any angle less than 30° from the direction perpendicular to the light output surface as measured over a wavelength range from about 300 nm to 1500 nm.
53. The light control film according to any of the preceding embodiments, wherein the film spectral transmission measured at a 60° incident angle varies by greater than 5% over a wavelength range from 400 nm to 750 nm.
54. The light control film according to any of the preceding embodiments, wherein a film made from the same material and having the same transmittance as the region 2, absorbs more than 50% in the wavelength range from 400 nm to 750 nm.
55. The light control film according to any of the preceding embodiments, wherein the film, observed at viewing angle greater than 30° reflects less than 10% of the incident visible light.
56. The light control film according to any of the preceding embodiments, wherein the region 1 material is integrally connected to a pigmented base substrate film layer.
57. The light control film according to any of the preceding embodiments, wherein the region 1 material comprises one or more UV stabilizers.
58. The light control film according to any of the preceding embodiments, wherein the region 2 material comprises one or more UV stabilizers.
59. The light control film according to any of the preceding embodiments, wherein the region 1 material and the region 2 material comprises, each independently of each other, one or more UV stabilizers.
60. The light control film according to any of the preceding embodiments, wherein the region 1 material is separately attached to a pigmented substrate film layer.
61. The light control film according to any of the preceding embodiments, wherein the pigmented base substrate film layer is of a different color than the region 2 color.
62. The light control film according to any of the preceding embodiments, wherein the base layer has an average reflectance of greater than 50% and the spectral reflectance measured within 10° of normal incidence varies by less than 5% over a wavelength range from 400 nm to 750 nm.
63. The light control film according to any of the preceding embodiments, wherein the base layer has an average reflectance of less than 50% and the spectral reflectance measured within 10° of normal incidence varies by greater than 5% over a wavelength range from 400 nm to 750 nm.
64. The light control film according to any of the preceding embodiments, wherein the base layer has an average reflectance of less than 50% and the spectral reflectance measured within 10° of normal incidence varies by greater than 5% when averaged over a wavelength range from 400 nm to 500 nm as compared to a wavelength range from 500 nm to 700 nm.
65. The light control film according to any of the preceding embodiments, wherein the base layer has an average reflectance of <50% and the solar weighted reflectance spectrum results in a CIE 1931 xyz color of x<0.3 and y<0.2.
66. The light control film according to any of the preceding embodiments, wherein the 30° incidence angle transmittance of the film is at least 50% in at least one of the following wavelength ranges:
   from 300 nm to 400 nm,
   from 400 nm to 750 nm,
   from 750 nm to 1500 nm.
67. The light control film according to any of the preceding embodiments, wherein the 30° incidence angle transmittance of the film is at least 60% in at least one of the following wavelength ranges:
   from 300 nm to 400 nm,
   from 400 nm to 750 nm,
   from 750 nm to 1500 nm.
68. The light control film according to any of the preceding embodiments, further comprising an adhesive layer immediately adjacent to one or both of the light input surface and light output surface.
69. The light control film according to any of the preceding embodiments, further comprising a pressure sensitive adhesive immediately adjacent to one or both of the light input surface and light output surface.
70. The light control film according to any of the preceding embodiments, further comprising an optically clear adhesive layer immediately adjacent to one or both of the light input surface and light output surface.
71. The light control film according to any of the preceding embodiments, further comprising an optically clear adhesive layer immediately adjacent to one or both of the light input surface and light output surface, and wherein the optically clear adhesive layer comprises an acrylic adhesive or a polyolefin material, or a combination thereof.
72. The light control film according to any of the preceding embodiments, further comprising a optically clear adhesive layer immediately adjacent to one or both of the light input surface and light output surface, wherein the optically clear adhesive is of sufficient cross-link density to withstand vacuum lamination temperatures up to 160 C for up to 30 minutes cycle time without undergoing significant creep.
73. The light control film according to any of the preceding embodiments, further comprising a optically clear adhesive layer immediately adjacent to one or both of the light input surface and light output surface, wherein the optically clear adhesive comprises one or more UV stabilizers.
74. A solar module comprising:
   a solar cell and
   a light control film according to any of the preceding embodiments.
75. A solar module according to any of the preceding embodiments directed to solar modules, wherein the light control film is adjacent the internal surface of the front-side layer of the solar module.

### EXAMPLES

The following examples are intended as illustrations only, since numerous modifications and variations within the scope of the present disclosure will be apparent to those skilled in the art. Unless otherwise noted, all parts, percentages, and ratios reported in the following examples are on a weight basis.

### Description of Examples and Comparative Examples

Examples 1, 2, and 3 are representative of absorbing material 350 resin sets of the described disclosure. Comparative Examples 1 and 2 are representative of absorbing material 350 resins used in commercially available light control films.

Examples 4-7 are exemplary light control films. Comparative Examples 3-6 are commercially available light control films. Comparative Example 7 illustrates the use of an IR-transmissive pigment in a light control film having similar dimensions as a commercially-available light control film.

### Absorbing Material 350 Resin Formulations

### Example 1

Resin was comprised of the following materials: 15 parts of a pigment masterbatch and 85 parts of a clear resin masterbatch. The pigment masterbatch was comprised of the following materials: 30 parts 9R341 pigment paste (commercially available from Penn Color Inc., Doylestown, Pa., USA) and 70 parts 9Y339 pigment paste (Penn Color). The clear resin masterbatch was comprised of the following materials: 91 parts Ebecryl 350 (Allnex USA Inc., Alpharetta, Ga., USA), 6.25 parts SR-285 (Sartomer Company, Exton, Pa., USA), 1.25 parts Darocur 1173 photoinitiator (BASF Corporation, Wyandotte, Mich., USA), and 1.25 parts Irgacure 819 photoinitiator (BASF Corporation, Wyandotte, Mich., USA).

### Example 2

Resin was comprised of the following materials: 12.5 parts 9B2108 pigment paste (Penn Color) and 87.5 parts same clear resin masterbatch used in Example 1.

### Example 3

Resin was comprised of the following materials: 25 parts 9B2108 pigment paste (Penn Color) and 75 parts same clear resin masterbatch used in Example 1.

### Comparative Example 1

Resin was comprised of the following materials: 20 parts 9B1173 pigment paste (Penn Color), 67 parts Photomer 6210 resin (IGM Resins USA Inc., Charlotte, N.C., USA), 10 parts SR-285 (Sartomer), 1 part each Irgacure 819, Irgacure 369, and Darocur 1173 (all from BASF).

### Comparative Example 2

Resin was comprised of the following materials: 20 parts 9B1639 pigment paste (Penn Color) and 80 parts of the same clear resin masterbatch used in Example 1.

### Preparation of Unstructured Films

Unstructured films of material 350 resins were prepared from hand pours for each solution made between two pieces of polyester (PET) film, one film chemically primed to promote adhesion of the resin to the PET film, and the other not primed. “Hand spread” coatings of each solution were made using a precision laboratory draw down coater (manufactured by ChemInstruments, West Chester Township, Ohio). The uncured resin was then exposed to ultraviolet light (UV) radiation (Model DRS-10/120N manufactured by Fusion UV Systems Inc., Gaithersburg, Md. @ 2 passes, 30 feet per minute, one-side exposure with a Fusion D bulb) to cure the polymerizable resin mixture. Final cured film thickness was about 37 microns (+/−4 microns) each.

### Preparation of Microstructured Films (Transparent Channel Films)

Structured films were made by molding and ultraviolet light (UV) curing a visible wavelength transparent photo-polymerizable composition on a 0.003″ gauge, chemically primed PET substrate film. For these structured films a cylindrically-shaped metal roll with finely detailed channels cut into its outer surface served as the mold. The resinous mixture was first introduced onto the PET substrate film and then pressed firmly against the metal roll in order to completely fill the mold. Upon polymerization the structured film was removed from the mold. The resulting structure in the cured resin was a series of evenly spaced channels, each having a nominally trapezoidal cross-section. FIG. 2 is representative of such a structured film.

### Preparation of Light Control Films

A material 350 resin described earlier was filled into the grooves between the transparent channels of the microstructured film prepared by the method described above. Excess pigment-containing resin was wiped from the outward-facing surfaces of the transparent channels. The pigment filled channels were then cured using UV radiation, resulting in a light control film similar to that shown in FIG. 3.

### Characterization of the Unstructured Films

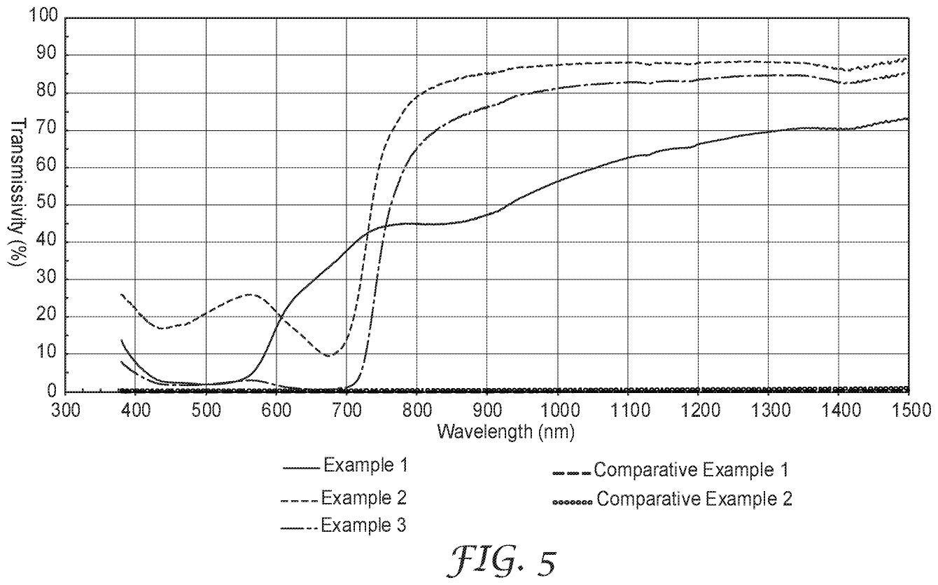

Unstructured films made using Examples 1, 2, and 3 and Comparative Examples 1 and 2 were analyzed as follows. First, the unprimed PET liner was removed from each sample film. Each sample was tested using an Oriel Brand diode array spectrophotometer for transmission (or transmittance, expressed as a percentage) at normal incidence (θ=0 in an air medium). The spectrophotometer was operated with a diffuse (Lambertian) light source and a light collimating detector. This is optically the same as using a collimated incident light beam and an integrating sphere detector. The spectral profiles for each example set are represented at FIG. 5. Table 1 represents the arithmetic average of the measured transmittance at normal incidence over two distinct spectral wavelength ranges for each example set.

TABLE 1
Average Transmittance for Unstructured Films.

| | Average Transmittance (%) | | | | |
|---|---|---|---|---|---|
| | | | | Comparative | Comparative |
| Wavelength Range | Example 1 | Example 2 | Example 3 | Example 1 | Example 2 |
| 400 nm to 750 nm | 16.6 | 21.5 | 3.4 | 0.0 | 0.2 |
| 750 nm to 1500 nm | 61.8 | 86.4 | 80.2 | 0.2 | 0.5 |

Example 2 and Example 3 material sets differ only in the pigment weight fraction of the resin. The Example 3 resin contains twice the pigment weight fraction as Example 2 resin. The Example 2 and Example 3 unstructured films were nearly identical film thickness. The resulting loss in transmittance for the Example 3 unstructured film is about 6 percentage point units compared to the Example 2 unstructured film over the wavelength range from 750 nm to 1500 nm. Using Beer's Law as a guide, one may reasonably expect that if the same Example 3 resin were coated at twice the thickness (about 74 microns compared to about 37 microns) on the same PET substrate film the resulting average transmittance would be about 70% over the wavelength range from 750 nm to 1500 nm.

### Characterization of the Light Control Films

For each light control film sample cross-sections were taken for the purpose of measuring the critical dimensions that characterize the performance of the light control film. A Keyence Microscope was used to measure the various dimensions. Reported in Tables 2 and 3 are average values representing at least five measurements for each dimension of each sample. Nomenclature in Tables 2 and 3 is consistent with that shown in FIGS. 1 and 3.

TABLE 2
Exemplary Light Control Films (micron unit of length dimensions).

| Description | Region 2 Resin | W₁ₐ | W_{1b} | P | H | ϕ_{I} | H/W_{1b} | W₁ₐ/P | θ_{T} |
|---|---|---|---|---|---|---|---|---|---|
| Example 4 | Example 1 | 47.5 | 48.9 | 55.3 | 68.5 | 71.2° | 1.40 | 0.86 | 1.4° |
| Example 5 | Example 2 | 47.5 | 48.9 | 55.3 | 68.5 | 71.2° | 1.40 | 0.86 | 1.4° |
| Example 6 | Example 3 | 47.5 | 48.9 | 55.3 | 68.5 | 71.2° | 1.40 | 0.86 | 1.4° |
| Example 7 | Comp Example 2 | 47.5 | 48.9 | 55.3 | 68.5 | 71.2° | 1.40 | 0.86 | 1.4° |

TABLE 3
Comparative Light Control Films (μm unit of length dimensions).

| Description | W₁ₐ | W_{1b} | P | H | ϕ_{I} | H/W_{1b} | W₁ₐ/P | θ_{T} |
|---|---|---|---|---|---|---|---|---|
| Comparative Example 3 | 30.7 | 31.8 | 38.0 | 88.8 | 38.7° | 2.79 | 0.81 | 0.8° |
| Comparative Example 4 | 49.6 | 56.0 | 63.0 | 146.9 | 38.8° | 2.62 | 0.79 | 2.4° |
| Comparative Example 5 | 46.2 | 56.0 | 63.5 | 145.4 | 39.3° | 2.60 | 0.73 | 4.0° |
| Comparative Example 6 | 34.9 | 29.3 | 39.2 | 100.0 | 35.3° | 2.86 | 0.75 | 3.3° |
| Comparative Example 7 | 46.9 | 51.4 | 64.2 | 146.9 | 38.0° | 2.86 | 0.73 | 1.6° |

Spectral transmittance data were generated for each sample using an Oriel Brand diode array spectrophotometer. Each sample was tested for transmission (or transmittance, expressed as a percentage) at normal incidence (ϕ=0 in an air medium) and at 30 degrees incidence (ϕ=30 degrees in an air medium) and in a direction perpendicular to the louvers. The spectrophotometer was operated with a diffuse (Lambertian) light source and a light collimating detector. This is optically the same as using a collimated incident light beam and an integrating sphere detector. The average measured transmittance over two distinct wavelength ranges for each of the exemplary and commercially available light control films listed in Tables 2 and 3 are represented at Table 4.

TABLE 4
Average Transmittance for Exemplary Light Control Films.

| | Average Transmittance (%) As Function of Measurement Angle | | | |
|---|---|---|---|---|
| | ϕ = Incidence Angle | | ϕ = 30° Incidence Angle | |
| Description | 400 nm to 750 nm | 750 nm to 1500 nm | 400 nm to 750 nm | 750 nm to 1500 nm |
| Example 4 | 83.8 | 87.8 | 63.0 | 76.9 |
| Example 5 | 83.6 | 90.5 | 63.4 | 84.7 |
| Example 6 | 81.5 | 89.5 | 52.1 | 76.6 |
| Example 7 | 81.5 | 81.1 | 48.1 | 48.7 |
| Comp. Ex. 3 | 65.0 | 64.1 | 3.4 | 4.2 |
| Comp. Ex. 4 | 65.7 | 67.1 | 0.6 | 0.6 |
| Comp. Ex. 5 | 68.9 | 70.1 | 11.0 | 12.3 |
| Comp. Ex. 6 | 71.6 | 72.8 | 9.8 | 8.4 |
| Comp. Ex. 7 | 81.0 | 86.2 | 24.0 | 54.7 |

### Example 4

Exemplifies a representative light control film characterized by: (a) H/W_{1b}=1.40; (b) W₁ₐ/P=0.86; (c) ϕ_{I}=71.2°; (d) average 0° incidence angle spectral transmittance between 750 nm and 1500 nm=87.8%; (e) average 30° incidence angle spectral transmittance between 750 nm and 1500 nm=76.9%.

### Example #5

Exemplifies a representative light control film characterized by: (a) H/W_{1b}=1.40; (b) W₁ₐ/P=0.86; (c) ϕ₁=71.2°; (d) average 0° incidence angle spectral transmittance between 750 nm and 1500 nm=90.5%; (e) average 30° incidence angle spectral transmittance between 750 nm and 1500 nm=84.7%.

### Example #6

Exemplifies a representative light control film characterized by: (a) H/W_{1b}=1.40; (b) W₁ₐ/P=0.86; (c) ϕ_{I}=71.2°; (d) average 0° incidence angle spectral transmittance between 750 nm and 1500 nm=89.5%; (e) average 30° incidence angle spectral transmittance between 750 nm and 1500 nm=76.6%.

### Example #7

Exemplifies a representative light control film characterized by: (a) H/W_{1b}=1.40; (b) W₁ₐ/P=0.86; (c) ϕ_{I}=71.2°; (d) average 0° incidence angle spectral transmittance between 750 nm and 1500 nm=81.1%; (e) average 30° incidence angle spectral transmittance between 750 nm and 1500 nm=48.7%.

### Comparative Example #3

Exemplifies a representative light control film characterized by: (a) H/W_{1b}=2.79; (b) W₁ₐ/P=0.81; (c) ϕ_{I}=38.7°; (d) average 0° incidence angle spectral transmittance between 750 nm and 1500 nm=64.1%; (e) average 30° incidence angle spectral transmittance between 750 nm and 1500 nm=4.2%. Comparative Example #3 light control film is sold by 3M Company under the Trade Name 3M Privacy Filter for Touch Laptops.

### Comparative Example #4

Exemplifies a representative light control film characterized by: (a) H/W_{1b}=2.62; (b) W₁ₐ/P=0.79; (c) ϕ_{I}=38.8°; (d) average 0° incidence angle spectral transmittance between 750 nm and 1500 nm=67.1%; (e) average 30° incidence angle spectral transmittance between 750 nm and 1500 nm=0.6%. Comparative Example #4 light control film is sold by 3M Company under the Trade Name 3M Privacy Filter.

### Comparative Example #5

Exemplifies a representative light control film characterized by: (a) H/W_{1b}=2.60; (b) W₁ₐ/P=0.73; (c) ϕ_{I}=39.3°; (d) average 0° incidence angle spectral transmittance between 750 nm and 1500 nm=70.1%; (e) average 30° incidence angle spectral transmittance between 750 nm and 1500 nm=12.3%. Comparative Example #5 light control film is sold by 3M Company under the Trade Name ALCF-A.

### Comparative Example #6

Exemplifies a representative light control film characterized by: (a) H/W_{1b}=2.86; (b) W₁ₐ/P=0.89; (c) (ϕ_{I}=35.3°; (d) average 0° incidence angle spectral transmittance between 750 nm and 1500 nm=72.8%; (e) average 30° incidence angle spectral transmittance between 750 nm and 1500 nm=8.4%. Comparative Example #6 light control film is sold by Dai Nippon Printing (Japan) under the Trade Name Louver Array Film.

### Comparative Example #7

Exemplifies a representative light control film characterized by: (a) H/W_{1b}=2.86; (b) W₁ₐ/P=0.73; (c) ϕ_{I}=38.0°; (d) average 0° incidence angle spectral transmittance between 750 nm and 1500 nm=86.2%; (e) average 30° incidence angle spectral transmittance between 750 nm and 1500 nm=54.7%.

1. A light control film comprising a structured layer comprising a plurality of regions 1 alternating with a plurality of regions 2,
wherein the structured layer has a light input surface and a light output surface opposite the light input surface,
wherein the plane of the light input surface defines a plane for the film,
wherein at least one region 1 has a width at its base W_{1b}, a height H₁, and an index of refraction N₁,
wherein at least one region 2 has a width at its base W_{2b}, a height H₂, and an index of refraction N₂,
wherein the lesser of H₁ and H₂ is the effective height, H,
wherein a first interface between the at least one region 1 and the at least one region 2 forms a first interface angle, θ₁, measured clockwise from a direction normal to the plane of the film,
wherein a second interface between the at least one region 1 and the at least one region 2 forms a second interface angle, θ₂, measured counterclockwise from a direction normal to the plane of the film,
wherein the 30° incidence angle transmittance of the film is at least 30% in at least one of the following wavelength ranges:
from 300 nm to 400 nm,
from 400 nm to 750 nm,
from 750 nm to 1500 nm.

2. The light control film according to claim 1, wherein the total 0° incidence angle transmittance of the film is at least 75% in at least one of the following wavelength ranges:
from 300 nm to 400 nm,
from 400 nm to 750 nm,
from 750 nm to 1500 nm.

3. The light control film according to claim 1, wherein N₁−N₂ is not less than 0.005.

4. The light control film according to claim 1, wherein the film has an internal viewing angle, ϕ_{I}, and wherein 50°≤ϕ_{I}≤88°.

5. The light control film according to claim 1, wherein the first interface angle, θ₁, is 3° or less.

6. The light control film according to claim 1, wherein the second interface angle, θ₂, is 3° or less.

7. The light control film according to claim 1, wherein H/W_{1b} ranges from 1.0 to 2.1.

8. The light control film according to claim 1, wherein W₁ₐ/P ranges from 0.8 to 0.95.

9. The light control film according to claim 1, wherein θₛₗₐₙₜ slant is defined as the absolute value of [(θ₂ minus θ₁)/2], and wherein 3°≤θₛₗₐₙₜ≤30°.

10. The light control film according to claim 1, wherein a film made of the same material, and having the same transmittance as the at least one region 1, has a 0° incidence angle transmittance of at least 70% in at least two of the following wavelength ranges:
from 300 nm to 400 nm,
from 400 nm to 750 nm,
from 750 nm to 1500 nm,
wherein a film made of the same material, and having the same transmittance as the at least one region 2, has a 0° incidence angle transmittance of at least 30% in one or two of the following wavelength ranges:
from 300 nm to 400 nm,
from 400 nm to 750 nm,
from 750 nm to 1500 nm.

11. The light control film according to claim 1, wherein solar light incident in a direction perpendicular to the light input surface exits the light output surface at greater than 70% of the maximum brightness measured at any angle less than 30° from the direction perpendicular to the light output surface as measured over a wavelength range from about 300 nm to 1500 nm.

12. The light control film according to claim 1, wherein the film spectral transmission measured at a 60° incident angle varies by greater than 5% over a wavelength range from 400 nm to 750 nm.

13. The light control film according to claim 1, wherein the region 1 material is integrally connected to a pigmented base substrate film layer.

14. The light control film according to claim 1, further comprising an optically clear adhesive layer immediately adjacent to one or both of the light input surface and light output surface.

15. A solar module comprising:
a solar cell and
a light control film according to claim 1.
